(19) United States
(12) Patent Application Publication
(10) Pub. No.: US 2025/0279397 A1
(43) Pub. Date: Sep. 4, 2025

(54) SEMICONDUCTOR STRUCTURE AND METHOD FOR MANUFACTURING A SEMICONDUCTOR STRUCTURE

(71) Applicant: AP MEMORY TECHNOLOGY CORPORATION, HSINCHU COUNTY (TW)

(72) Inventors: KEE-WEI CHUNG, HSINCHU COUNTY (TW); RU-YI CAI, HSINCHU COUNTY (TW); WEN-LIANG CHEN, HSINCHU COUNTY (TW); CHIN-HUNG LIU, HSINCHU COUNTY (TW)

(21) Appl. No.: 18/594,934

(22) Filed: Mar. 4, 2024

(51) Int. Cl. H01L 25/065; H01L 23/00; H01L 23/48; H01L 23/522; H01L 23/528; H01L 25/00; H01L 25/18

(52) U.S. Cl. CPC H01L 25/0657; H01L 23/481; H01L 23/5223; H01L 23/5283; H01L 23/5286; H01L 24/32; H01L 24/94; H01L 25/18; H01L 25/50; H01L 2224/32145; H01L 2224/94; H01L 2924/1205

(57) ABSTRACT

The present application discloses a semiconductor package and a method for manufacturing the semiconductor package. The semiconductor package includes a first dielectric, a first redistribution layer (RDL) disposed on a first surface of the first dielectric, a first bonding layer disposed on the first RDL, a plurality of bottom dies attached to the first bonding layer, a second dielectric filling gaps between the bottom dies, a plurality of conductive pillars disposed in the second dielectric without contacting the bottom dies, a second RDL disposed on the second dielectric and the bottom dies, a second bonding layer disposed on the second RDL, a plurality of top dies attached to the second bonding layer, a third dielectric filling gaps between the top dies, and a plurality of solder bumps disposed on a second surface of the first dielectric.

### TECHNICAL FIELD

The present disclosure relates to a semiconductor structure, and more particularly, to a semiconductor structure having a power management integrated circuit stacking on silicon capacitor layers.

### BACKGROUND

In electronic devices, different components and modules often require different voltages to operate. Therefore, electronic devices need to convert input voltages, such as a battery voltage or a USB power supply voltage, into different voltage rails to meet the needs of various components and modules. To facilitate power management, electronic devices often adopt power management integrated circuits (PMIC) to perform voltage conversion and provide multiple voltages required by the system.

Voltage conversion circuits in the PMIC often require passive components, such as capacitors, to store energy. The quality and quantity of these passive components can significantly impact the power efficiency of conversion process. However, due to the large area occupied by passive components, electronic devices with limited space may face trade-off between area and power efficiency. Conventionally, a PMIC and capacitors are typically placed on a same substrate and connected through conductive traces within the substrate. In such case, the conductive paths between the PMIC and the capacitors can be rather long and may cross different material interfaces, which results in poor signal integrity and power integrity. Therefore, how to improve the efficiency of voltage conversion remains a problem to be solved.

### SUMMARY

One aspect of the present disclosure provides a semiconductor structure. The semiconductor structure includes a first chip, a second chip, a first bonding layer, and a power management die. The first chip has a first 3-dimensional (3D) capacitor structure therein, and the second chip has a second 3D capacitor structure therein. The first bonding layer bonds the first chip with the second chip. The power management die is bonded with the second chip. The power management die is electrically connected to the first 3D capacitor structure and the second 3D capacitor structure through interconnects extending along a thickness of the semiconductor structure and across the first bonding layer.

Another aspect of the present disclosure provides a semiconductor device. The semiconductor device includes a printed circuit board (PCB), a substrate, a system on chip (SoC), and the semiconductor structure aforementioned. The substrate is disposed on the PCB, and the SoC is disposed on a first surface of the substrate. The semiconductor structure is coupled to the SoC.

Another aspect of the present disclosure provides a method for manufacturing a semiconductor structure. The method includes forming a bonding between a first wafer having a plurality of first 3D capacitor structures therein and a second wafer having a plurality of second 3D capacitor structures therein to bond the first wafer with the second wafer, bonding a plurality of power management dies over the second wafer, and performing a sawing process to form the semiconductor structure including a first chip, a second chip, a first bonding layer, one of the plurality of power management dies, one of the plurality of first 3D capacitor structures in the first chip and one of the plurality of second 3D capacitor structures in the second chip. The power management die is electrically connected to the first 3D capacitor structure and the second 3D capacitor structure through interconnects extending along a thickness of the semiconductor structure and across the first bonding layer.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a semiconductor structure according to one embodiment of the present disclosure.

FIG. 2 shows a flow chart of a method for manufacturing the semiconductor structure in FIG. 1 according to one embodiment of the present disclosure.

FIGS. 3A to 3K show cross-sectional view or side view of one or more stages for manufacturing the semiconductor structure in FIG. 1 according to one embodiment of the present disclosure.

FIG. 4 shows a semiconductor structure according to one embodiment of the present disclosure.

FIGS. 5A to 5H show cross-sectional view of one or more stages for manufacturing the semiconductor structure in FIG. 4 according to one embodiment of the present disclosure.

FIG. 6 shows a semiconductor structure according to one embodiment of the present disclosure.

FIGS. 7A to 7H show cross-sectional view of one or more stages for manufacturing the semiconductor structure in FIG. 6 according to one embodiment of the present disclosure.

FIG. 8 shows a semiconductor structure according to one embodiment of the present disclosure.

FIGS. 9A to 9D show cross-sectional view of one or more stages for manufacturing the semiconductor structure in FIG. 8 according to one embodiment of the present disclosure.

FIGS. 10A to 10E show cross-sectional view of one or more stages for manufacturing the semiconductor structure in FIG. 6 according to one embodiment of the present disclosure.

FIG. 11 shows a semiconductor structure according to one embodiment of the present disclosure.

FIGS. 12A to 12K show cross-sectional view of one or more stages for manufacturing the semiconductor structure in FIG. 11 according to one embodiment of the present disclosure.

FIG. 13 shows a semiconductor structure according to one embodiment of the present disclosure.

FIGS. 14A to 14H show cross-sectional view of one or more stages for manufacturing the semiconductor structure in FIG. 13 according to one embodiment of the present disclosure.

FIGS. 15A to 15E show cross-sectional view of one or more stages for manufacturing the semiconductor structure in FIG. 13 according to one embodiment of the present disclosure.

FIG. 16 shows a semiconductor structure according to one embodiment of the present disclosure.

FIGS. 17A to 17E show cross-sectional view of one or more stages for manufacturing the semiconductor structure in FIG. 16 according to one embodiment of the present disclosure.

FIGS. 18 to 22 show semiconductor devices according to embodiments of the present disclosure.

FIG. 23 shows a cross-sectional view of a 3D capacitor structure according to some embodiments of the present disclosure.

FIG. 24 shows a cross-sectional view of a 3D capacitor structure according to some embodiments of the present disclosure.

FIG. 25A shows a top view of a rectangular-array-arrangement of 3D capacitor unit cells according to some embodiments of the present disclosure.

FIG. 25B shows a top view of a hexagonal-array-arrangement of 3D capacitor unit cells according to some embodiments of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

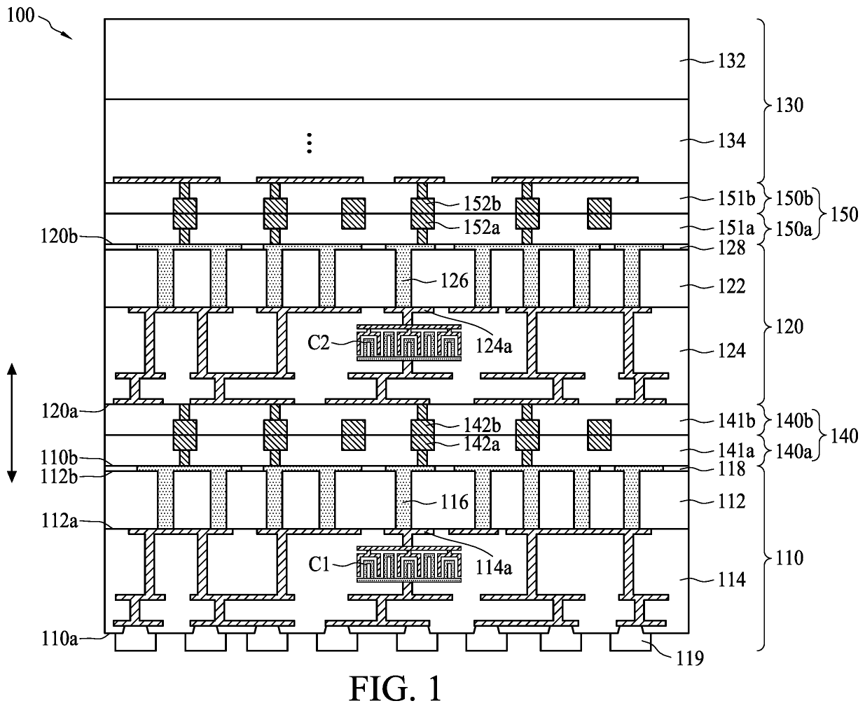

FIG. 1 shows a semiconductor structure 100 according to one embodiment of the present disclosure. The semiconductor structure 100 includes a chip 110, a chip 120, a power management die 130, and a bonding layer 140. The bonding layer 140 bonds the chip 110 with the chip 120, and the power management die 130 is bonded with the chip 120. In the present embodiment, the semiconductor structure 100 further includes a bonding layer 150, and the power management die 130 is bonded with the chip 120 by the bonding layer 150.

In some embodiments, the chip 110 and the chip 120 can be capacitor chips that each includes at least one 3D capacitor structure formed therein. For example, the chip 110 includes at least one 3D capacitor structure C1, the chip 120 includes at least one 3D capacitor structure C2. In some embodiments, the chip 110 and the chip 120 may be identical or having similar layouts. Thus, the 3D capacitor structure C1 may be aligned with the 3D capacitor structure C2. In some embodiments, the 3D capacitor structure C1 is vertically aligned with the 3D capacitor structure C2. In some embodiments, from a top view of the semiconductors structure 100, the 3D capacitor structure C1 overlaps with the 3D capacitor structure C2. However, the present disclosure is not limited thereto.

The power management die 130 can be a logic die that includes a power management integrated circuit (PMIC). The PMIC can be adopted to convert a supply voltage into different voltage rails required by components in a system. In the present embodiment, the power management die 130 can be coupled to the capacitors, such as the 3D capacitor structures C1 and C2, in the chip 110 and the chip 120 for voltage conversion. In such case, the power management die 130 is electrically connected to the 3D capacitor structure C1 and the 3D capacitor structure C2 at least through interconnects extending along a thickness (as shown by an arrow in FIG. 1) of the semiconductor structure 100. That is, the stacked structure of the chip 110, the chip 120 and the power management die 130 allows the power management die 130 to couple to the 3D capacitor structure C1 formed in the chip 110 through conductive paths crossing the bonding layer 140 and the bonding layer 150 and to couple to the 3D capacitor structure C2 formed in the chip 120 through conductive paths crossing the bonding layer 150. As a result, the power management die 130 can be coupled to the capacitance provided by the chips 110 and 120 in a smaller area with shorter routing distances, thereby improving the power efficiency, the signal integrity, and the power integrity.

As shown in FIG. 1, the chip 110 may include a semiconductive layer 112, a dielectric 114, at least one via 116, and a redistribution layer (RDL) 118. In some embodiments, the semiconductive layer 112 may include semiconductive material such as silicon, germanium, gallium, arsenic, or a combination thereof. In some embodiments, the semiconductive layer 112 can be a wafer substrate. In some embodiments, the semiconductive layer 112 is a silicon substrate. In some embodiments, the semiconductive layer 112 includes a first surface 112a and a second surface 112b opposite to the first surface 112a. The first surface 112a is in proximity to dielectric 114, and the second surface 112b is farther away from the dielectric 114. In some embodiments, the via 116 extends through the semiconductive layer 112 from the first surface 112a to the second surface 112b. In some embodiments, the semiconductive layer 112 is a silicon substrate, and the via 116 is a through silicon via (TSV).

The dielectric 114 is disposed over the semiconductive layer 112. In some embodiments, the dielectric 114 is disposed on the first surface 112a of the semiconductive layer 112. In some embodiments, the dielectric 114 includes dielectric material, such as silicon oxide, silicon nitride, polymer, or the like. In some embodiments, the dielectric 114 includes several dielectrics layers stacking over each other. In some embodiments, the dielectrics includes same material or different materials. In some embodiments, the dielectric 114 is interlayer dielectric (ILD).

In some embodiments, at least one interconnect structure 114a and the at least one 3D capacitor structure C1 are formed within the dielectric 114. In some embodiments, the interconnect structure 114a is an electrical routing within the chip 110. For example, the interconnect structure 114a may include metal lines that extend laterally at different levels and metal vias that extend vertically for connecting metal lines at different levels. In some embodiments, the interconnect structure 114a is formed in a back end of line (BEOL) process.

As shown in FIG. 1, the chip 110 further includes a plurality of conductive bumps 119. The conductive bumps 119 can be solder balls or copper pillars that are coupled to the interconnect structure 114a formed in the dielectric 114 for external connections of the semiconductor structure 100. In some embodiments, the conductive bumps 119 may include conductive material, such as copper, tin, silver, lead, alloy of the aforementioned materials, or the like.

The chip 110 has a first surface 110a and a second surface 110b opposite to the first surface 110a. In some embodiments, the first surface 110a is in proximity to dielectric 114 and is referred as a front side of the chip 110, and the second surface 110b is in proximity to semiconductive layer 112 with the via 116 and is referred as a back side of the chip 110.

As shown in FIG. 1, the conductive bumps 119 are disposed on the first surface 110a. In addition, the bonding layer 140 can contact the RDL 118 at the second surface 110b of the chip 110. In some embodiments, the bonding layer 140 can be formed by bonding a sub-bonding layer 140a with a sub-bonding layer 140b.

The sub-bonding layer 140a includes a bonding dielectric 141a and at least one bonding pad 142a. In some embodiments, the bonding pad 142a is surrounded by and at least partially exposed through the bonding dielectric 141a. In some embodiments, to facilitate the connection between the via 116 in the semiconductive layer 112 and the first bonding pads 142a in the sub-bonding layer 140a, the RDL 118 is dispose over the semiconductive layer 112 and is coupled to the via 116 and the bonding pad 142a. Although FIG. 1 only shows one layer of metal in the RDL 118, the present disclosure is not limited thereto. In some other embodiments, the RDL 118 may include more layers of metals with interlayer dielectrics formed there in for separating the different layers of metals.

In some embodiments, the bonding pad 142a extends through the bonding dielectric 141a to electrically connect to the metal lines in the RDL 118. Thus, the bonding pad 142a can be electrically connected to the first 3D capacitor structure C1 through the RDL 118, the via 116, and the interconnect structure 114a. In some embodiments, the bonding pad 142a includes conductive material such as copper, silver or the like.

In some embodiments, the chip 120 and the chip 110 may have similar structures. For example, the chip 120 includes a dielectric 124, a semiconductive layer 122 over the dielectric 124, at least one via 126 extending through the semiconductive layer 122, and a RDL 128 over the semiconductive layer 122. As shown in FIG. 1, the chip 120 has a first surface 120a and a second surface 120b opposite to the first surface 120a. In some embodiments, the first surface 120a is referred as a front side of the chip 120, and the second surface 120b is referred as a back side of the chip 120. However, unlike the chip 110, instead of having conductive bumps 119 disposed on the first surface 110a, the sub-bonding layer 140b is disposed on the first surface 120a of the chip 120. The sub-bonding layer 140b includes a bonding dielectric 141b and at least one bonding pad 142b. In some embodiments, the bonding pad 142b is surrounded by and at least partially exposed through the bonding dielectric 141b. In some embodiments, the bonding pad 142b extends through the bonding dielectric 141b to electrically connect to the interconnect structure 124a formed in the dielectric 124.

In some embodiments, the sub-bonding layer 140a and the sub-bonding layer 140b can be bonded through a hybrid bonding process so as to form the bonding layer 140. In some embodiments, the bonding pad 142a and the bonding pad 142b are aligned, so as to facilitate the hybrid bonding process. During the hybrid bonding process, the initial bond occurs at the dielectric-to-dielectric interface at room temperature under atmospheric conditions. The copper metal-to-metal connection is formed via annealing and metal diffusion.

As a result, the chip 110 can be bonded to the chip 120, thereby forming a stacked structure. Similarly, the PMIC die 130 can be bonded to the chip 120 by performing a hybrid bonding process. For example, the bonding layer 150 can be formed by bonding a sub-bonding layer 150a disposed on the chip 120 and a sub-bonding layer 150b disposed on the power management die 130.

In some embodiments, the sub-bonding layer 150a is disposed over the RDL 128 formed on the semiconductive layer 122. The sub-bonding layer 150a includes a bonding dielectric 151a and at least one bonding pad 152a. The bonding pad 152a extends through the bonding dielectric 151a to electrically connect to the metal lines in the RDL 128.

The sub-bonding layer 150b is disposed over the power management die 130, and includes a bonding dielectric 151b and at least one bonding pad 152b. In some embodiments, the bonding pad 152b is aligned with the bonding pad 152a, so that after the hybrid bonding process, the bonding pad 152b can be bonded to the bonding pad 152a. As a result, voltage conversion circuits (not shown) formed in the semiconductive layer 132 and the dielectric 134 in the power management die 130 can be coupled to the 3D capacitor structure C2 in the chip 120 through the bonding layer 150, the RDL 128, the via 126, and the interconnect structure 124a, and can be coupled to the 3D capacitor structure C1 in the chip 110 through the bonding layer 150, the RDL 128, the via 126, the interconnect structures 124a, the bonding layer 140, the RDL 118, the via 116, and the interconnect structures 114a.

Since the power management die 130 can be coupled to the 3D capacitor structure C1 and the 3D capacitor structure C2 through interconnects extending along the thickness (i.e., along the stacking direction as shown by the arrow in FIG. 1) of the semiconductor structure 100, the routing distances between the power management die 130 and the capacitors can be shortened, therefore, the signal integrity as well as the power integrity can be improved. Furthermore, since the stacked structure of the chip 110 and the chip 120 allows to integrate more capacitors within a small area to increase capacitance density, the power efficiency of the power management die 130 can also be improved.

In some embodiments, the 3D capacitor structure C1 can be a 3D metal insulator metal (MIM) capacitor, while such out-of-plane dimension can be advantageously used to increase effective MIM area and related capacitance density. In some embodiments, the 3D capacitor structure C1 in the present disclosure may have a very high density, for example, higher than about 1 μ/mm². In some embodiments, the 3D capacitor structure can be a cylinder capacitor.

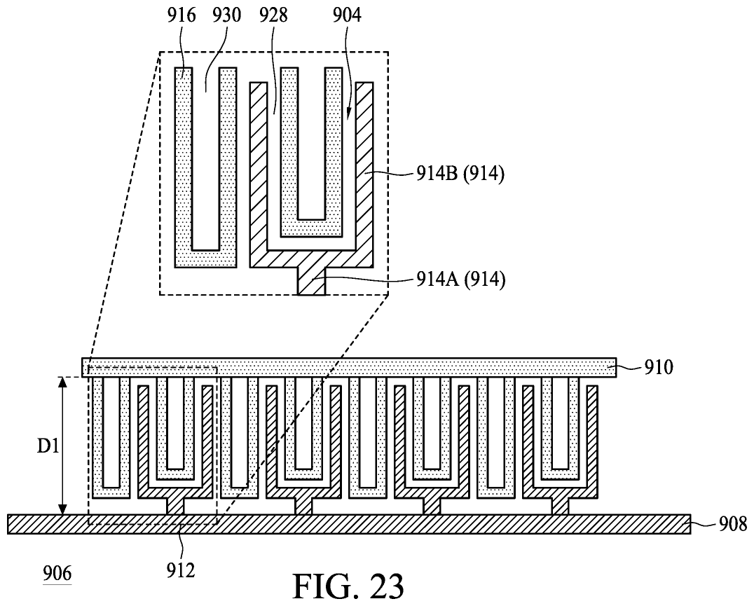

As shown in FIG. 23, in some embodiments, each of the 3D capacitor structures C1 includes a bottom metal plate 908, a top metal plate 910 over the bottom metal plate 908, and a plurality of 3D capacitor unit cells 912 are formed between the bottom metal plate 908 and the top metal plate 910. In some embodiments, a distance D1 between the bottom metal plate 908 and the top metal plate 910 is in a range of from about 1 μm to about 2 μm, which is much thinner than active or passive device components that are formed with deep trenches.

The configuration of the 3D capacitor unit cells 912 can have a crown-type capacitive structure or a concave-type capacitive structure. As illustrated in FIG. 23, in the embodiment that each of the 3D capacitor unit cells 912 are formed in crown type, the 3D capacitor unit cell 912 includes a first conductor film 914 and a second conductor film 916 stacked between the bottom metal plate 908 and the top metal plate 910. In some embodiments, the first conductor film 914 includes a first portion 914A connected to the bottom metal plate 908, and a second portion 914B connected to the first portion 914A and extending toward the top metal plate 910 from the bottom metal plate 908. In some embodiments, the second conductor film 916 is disposed adjacent to the first conductor film 914 and connected to the top metal plate 910, and extending toward the bottom metal plate 908 from the top metal plate 910. In some embodiments, the second conductor film 916 is vertically interleaving with the second portion 914B of the first conductor film 914. For instance, as the cross-sectional view shown in the figure, the second conductor film 916 is located adjacent to the inner and outer sides of an accommodated space 904. This accommodated space 904 is rounded by the first conductor film 914. In some embodiments, the second portion 914B can have a cylindrical shape, and the 3D capacitor structures C1 can be a cylindrical-type of capacitor.

Moreover, the 3D capacitor unit cell 912 further includes a first insulating film 928 for isolating the first conductor film 914 and the second conductor film 916. In other words, the MIM feature of the 3D capacitor structure C1 is performed by the stack of the first conductor film 914, the first insulating film 928, and the second conductor film 916. As shown in FIG. 23, in some embodiments, a second insulating film 930 can optionally be utilized to fill the space between the second conductor film 916 and the top metal plate 910. In some embodiments, the first insulating film 928 and the second insulating film 930 are composed of high-k dielectric material. For example, the high-k dielectric material may contain at least one of the oxides of Lanthanum, Hafnium, and Zirconium.

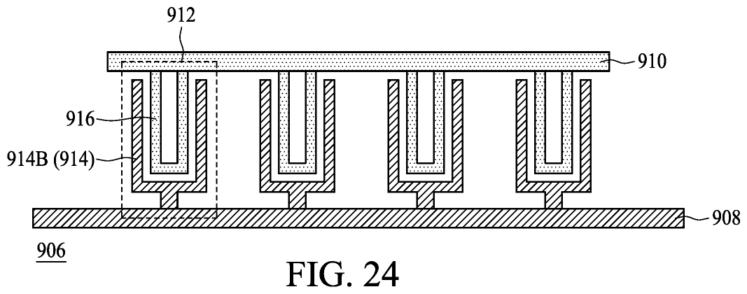

As shown in FIG. 24, in other embodiments, the 3D capacitor unit cell 912 are formed in concave type, the 3D capacitor unit cell 912 also includes the first conductor film 914 and the second conductor film 916 stacked between the bottom metal plate 908 and the top metal plate 910. In such embodiments, the second conductor film 916 is also formed adjacent to the first conductor film 914 and connected to the top metal plate 910, and extending toward the bottom metal plate 908 from the top metal plate 910. Comparing to the crown type shown in FIG. 23, the second conductor film 916 is laterally surrounded by the second portion 914B of the first conductor film 914 in each of the concave type capacitor cells 912, instead of entirely adjacent to inner and outer sides of the accommodated space 904 rounded by the first conductor film 914.

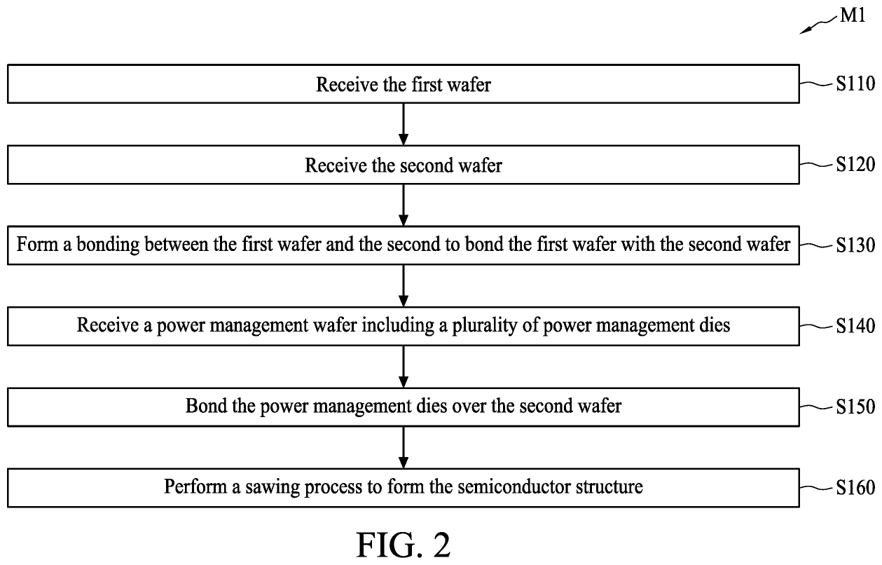

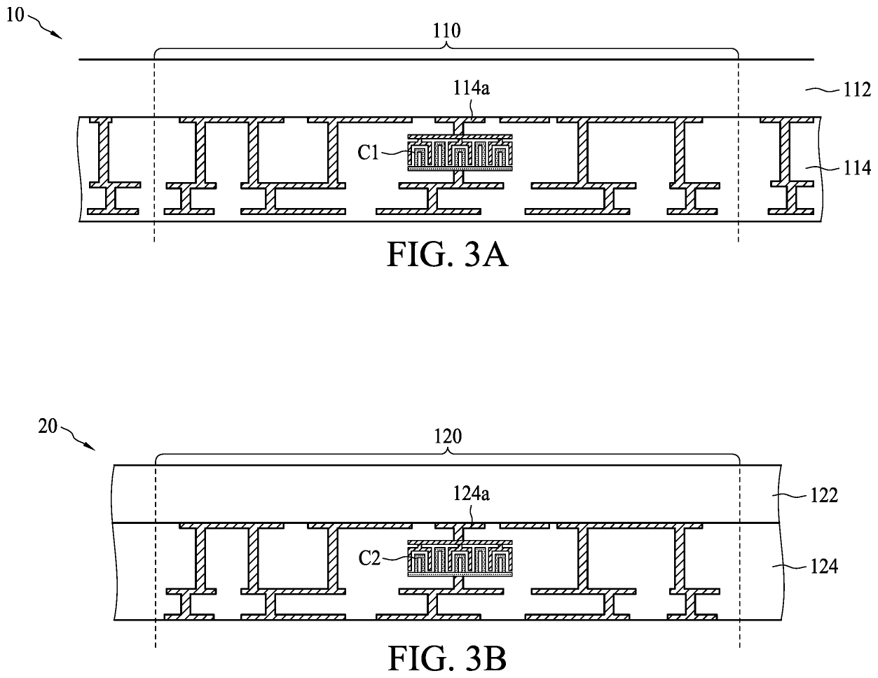

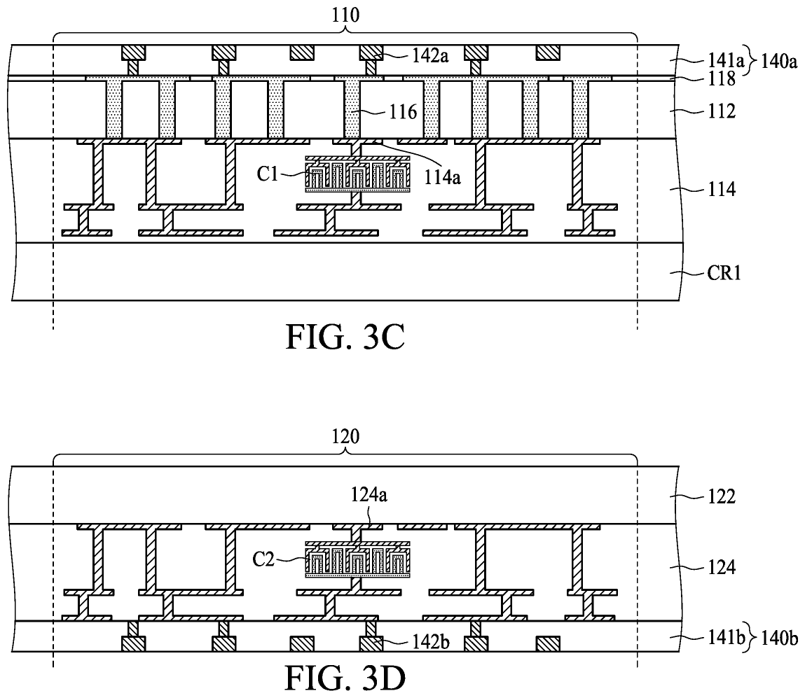

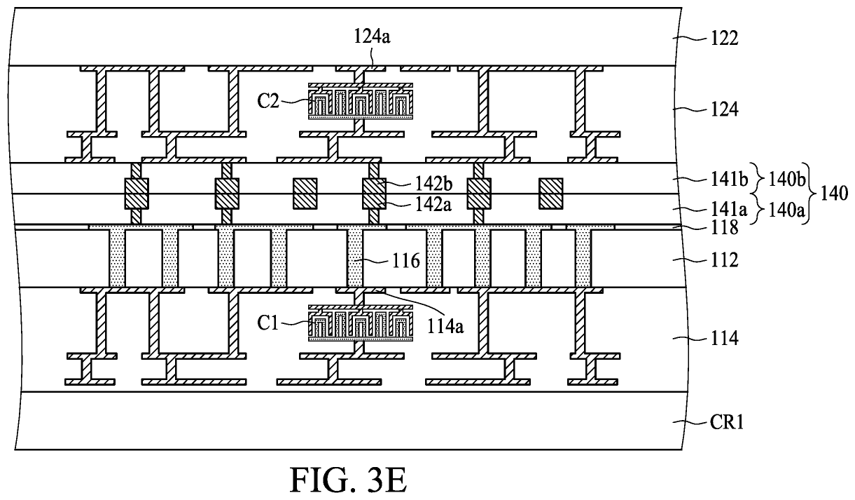

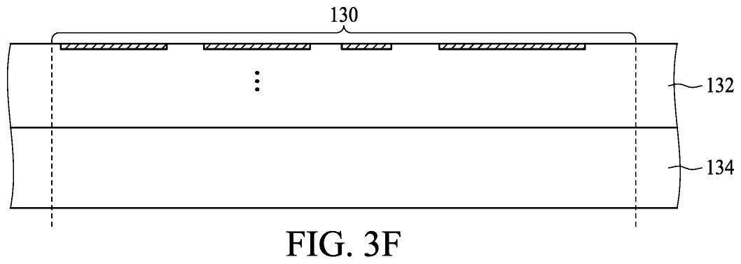

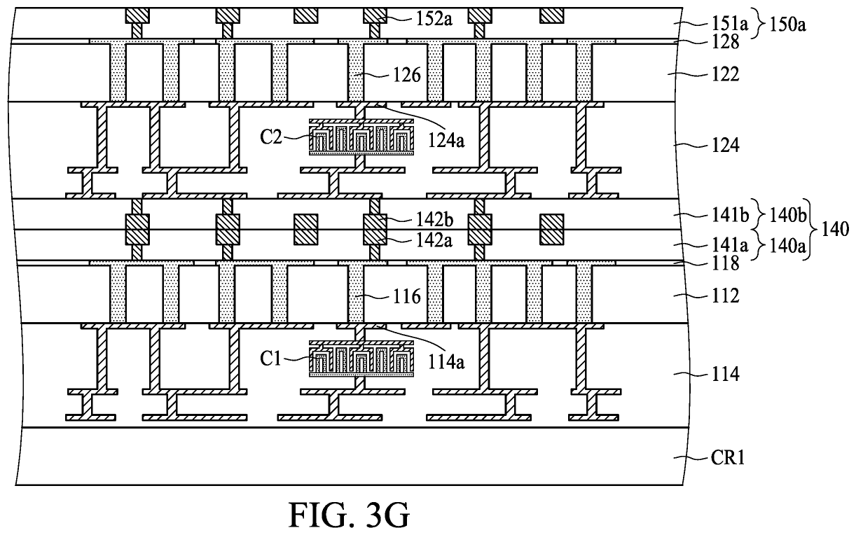

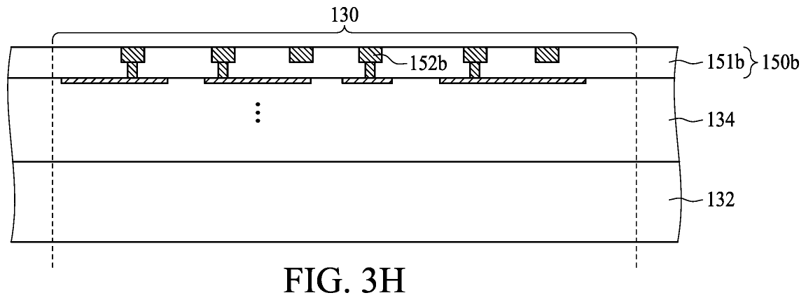

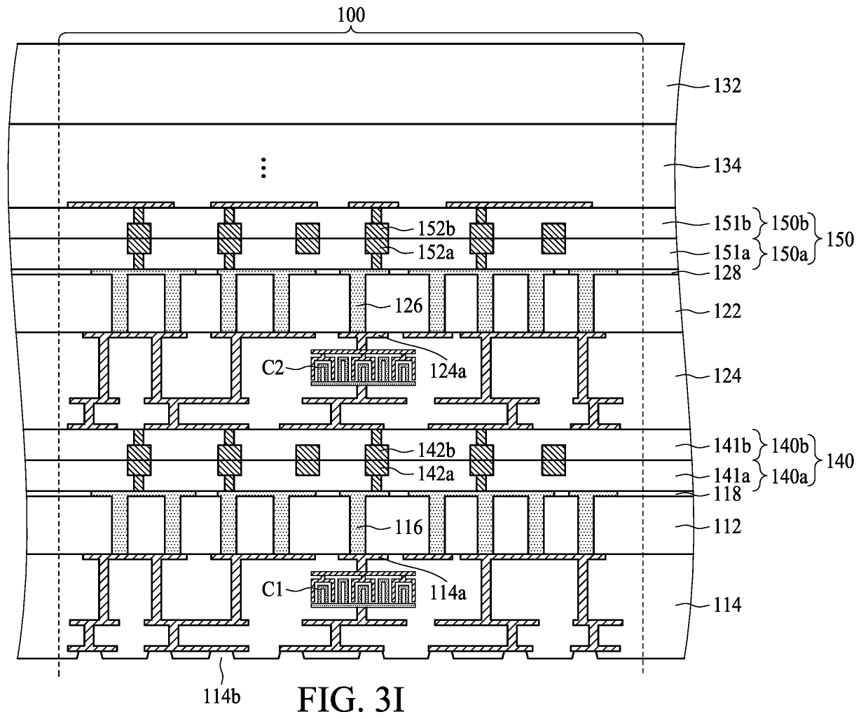

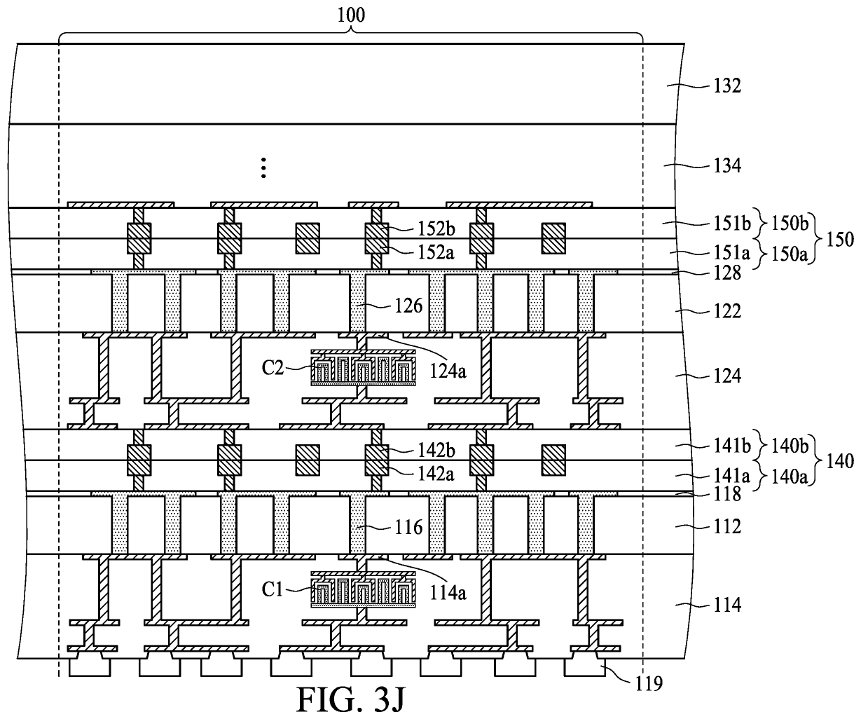

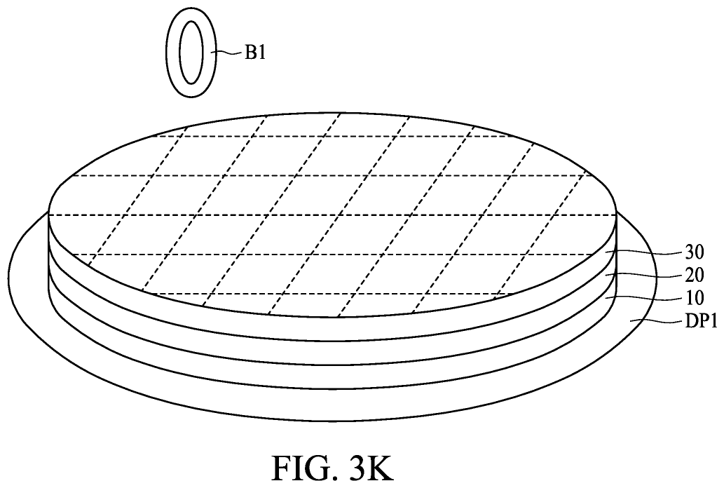

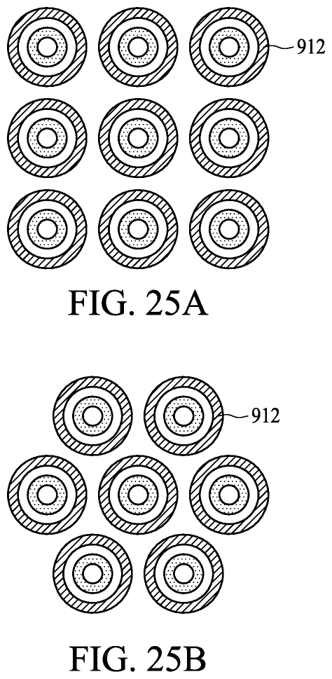

FIGS. 25A and 25B are top view diagrams illustrating a plurality of 3D capacitor unit cells 912 (concave type) according to some embodiments of the present disclosure. As shown in FIG. 25A, in some embodiments, the plurality of 3D capacitor unit cells 912 can be arranged to be a rectangular array between the metal plates (i.e., the bottom metal plate 908 and the top metal plate 910 previously shown in FIGS. 2 and 3) of the capacitor from a top view perspective. Alternatively, in other embodiments, as shown in FIG. 25B, the 3D capacitor unit cells 912 can be arranged to be a hexagonal array between the metal plates of the capacitor from a top view perspective. Generally, the hexagonal-array-arrangement may provide a higher density of the 3D capacitor unit cells 912. The arrangement of the 3D capacitor unit cells 912 of the present disclosure is not limited to the embodiments shown in FIG. 25A and 25B, because the 3D capacitor unit cells 912 may be arranged to be any symmetrical shape depending on the requirement.

In some embodiments, with the 3D capacitor structure C1 and C2 utilizing the 3D capacitor unit cells 912, a capacitance density of the chip 110 and a capacitance density of the chip 120 can be respectively greater than 1 μF/mm². By stacking the chip 110 and the chip 120, the capacitance density of the semiconductor structure 100 can be even doubled. In some embodiments, to further improve the power efficiency of the power management die 130, more number of capacitor chips can be stacked in the semiconductor structure 100. For example, in some embodiments, when two capacitor chips are stacked, the capacitance density may reach 5 μF/mm² and the power efficiency can be up to 85%. In addition, in some embodiments, when six capacitor chips are stacked, the capacitance density may reach 15 μF/mm² and the power efficiency can be up to 90%, and so on.

FIG. 2 shows a flow chart of a method M1 for manufacturing the semiconductor structure 100 according to one embodiment of the present disclosure. The method M1 includes steps S110 to S160, but is not limited by the performing order shown in FIG. 2. FIGS. 3A to 3K show cross-sectional view of one or more stages of the method M1 for manufacturing the semiconductor structure 100 according to one embodiment of the present disclosure.

In steps S110 and S120, a wafer 10 and a wafer 20 are received. In some embodiments, a plurality of first chips 110 are formed in the wafer 10, and a plurality of second chips 120 are formed in the wafer 20. As shown in FIG. 3A, the wafer 10 includes the dielectric 114, and the semiconductive layer 112 over the dielectric 114. The 3D capacitor structure C1 and the interconnect structure 114a are formed within the dielectric 114. In some embodiments, the wafer 20 and the wafer 10 can be identical to each other. However, the present disclosure is not limited thereto. As shown in FIG. 3B, the wafer 20 includes the dielectric 124, and the semiconductive layer 122 over the dielectric 124. The 3D capacitor structure C2 and the interconnect structure 124a are formed within the dielectric 124.

In step S130, a bonding is formed between the wafer 10 and the wafer 20. In some embodiments, such bonding can be formed by forming the sub-bonding layer 140a on the wafer 10 as shown in FIG. 3C, forming the sub-bonding layer 140b on the wafer 20 as shown in FIG. 3D, and bonding the sub-bonding layer 140a to the sub-bonding layer 140b as shown in FIG. 3E.

In some embodiments, as shown in FIG. 3C, the vias 116 in the semiconductive layer 112 can be formed in a via last (VL) manner. In such case, before forming the sub-bonding layer 140a, the semiconductive layer 112 can be thinned so as to form the via 116 extending through the semiconductive layer 112. In some embodiments, to provide the supporting strength when forming the via 116, a carrier CR1 can be attached on the dielectric 114 in advance (i.e. before the formation of the via 116). In some embodiments, the carrier CR1 can be a glass carrier, and can be attached to the dielectric 114 through an adhesion layer (not shown) that is removable (e.g., by heating or laser). After the via 116 is formed, the RDL 118 can be formed over the semiconductive layer 112 and the via 116, and then the sub-bonding layer 140a can be formed on the RDL 118.

For the wafer 20, the sub-bonding layer 140b is formed on the dielectric 124 as shown in FIG. 3D. In such case, since the semiconductive layer 122, which can be a part of a wafer or a substrate, is able to provide the supporting strength for forming the sub-bonding layer 140b, a carrier may not be necessary during the formation of the sub-bonding layer 140b.

After the sub-bonding layer 140a and the sub-bonding layer 140b are formed, the sub-bonding layer 140a and the sub-bonding layer 140b can be bonded to form the bonding layer 140 by performing a hybrid bonding process so that the wafer 10 and the wafer 20 can be bonded as shown in FIG. 3E in step S130.

In step S140, a power management wafer 30 is received as shown in FIG. 3F. In some embodiments, a plurality of power management dies 130 are formed in the power management wafer 30. Furthermore, in step S150, the power management die 130 is bonded over the wafer 20 by bonding the power management wafer 30 on the wafer 20. That is, the power management dies 130 can be stacked on the second chips 120 in a wafer-on-wafer (WoW) manner.

In some embodiments, to bond the power management wafer 30 on the wafer 20, the sub-bonding layer 150a over the wafer 20 and the sub-bonding layer 150b over the power management wafer 30 can be formed first, and then, the two sub-bonding layer 150a and 150b can be bonded by a hybrid bonding process so as to form the bonding layer 150 that bonds the wafer 20 and the power management wafer 30.

As shown in FIG. 3G, before the sub-bonding layer 150a is formed, the via 126 can be formed in the semiconductive layer 122, and the RDL 128 can be formed on the semiconductive layer 122 and the via 126. In some embodiments, to form the via 126 that extends through the semiconductive layer 122 with finer pitches and sizes, the semiconductive layer 122 may be ground to be thinned down before forming the via 126. After the RDL 128 is formed, the sub-bonding layer 150a is formed on the RDL 128.

Furthermore, as shown in FIG. 3H, the sub-bonding layer 150b is formed on the dielectric 134 of the power management wafer 30. Afterwards, the sub-bonding layer 150a is bonded to the sub-bonding layer 150b; as a result, the power management wafer 30 can be bonded over the wafer 20 as shown in FIG. 3I.

Furthermore, as shown in FIG. 3I, after the power management wafer 30 is bonded to the wafer 20, the carrier CR1 can be removed from the dielectric 114 of the wafer 10, and openings 114b can be formed on the surface of the dielectric 114 so that the conductive bumps 119 can be formed on the dielectric 114 and coupled to the interconnect structures 114a formed in the dielectric 114 as shown in FIG. 3J. However, the present disclosure is not limited thereto. In some embodiments, another passivation layer may be formed on the dielectric 114 so as to facilitate the formation of the conductive bumps 119 thereon.

In step S160, the stacked structure of the wafer 10, the wafer 20, and the power management wafer 30 can be sawn by performing a sawing process as shown in FIG. 3K, and the semiconductor structure 100 can be singulated from the stacked wafers. In such case, edges of the power management die 130 can be aligned with edges of the chip 110 and edges of the chip 120. In some embodiments, the wafer 10 can be attached to a dicing tape DP1, and the blade B1 can cut the stacked structure from the surface of the power management wafer 30. However, the present disclosure is not limited thereto. In some other embodiments, the back side of the power management wafer 30 can be attached to the dicing tape DP1, and the blade B1 can cut the stacked structure from the surface of the wafer 10.

In the semiconductor structure 100, the chip 110 and the chip 120 are stacked with the back side of the chip 110 facing the front side of the chip 120 (i.e., in a front-to-back manner), that is, the semiconductive layer 112 of the chip 110 is in proximity to the dielectric 124 of the chip 120. However, the present disclosure is not limited thereto.

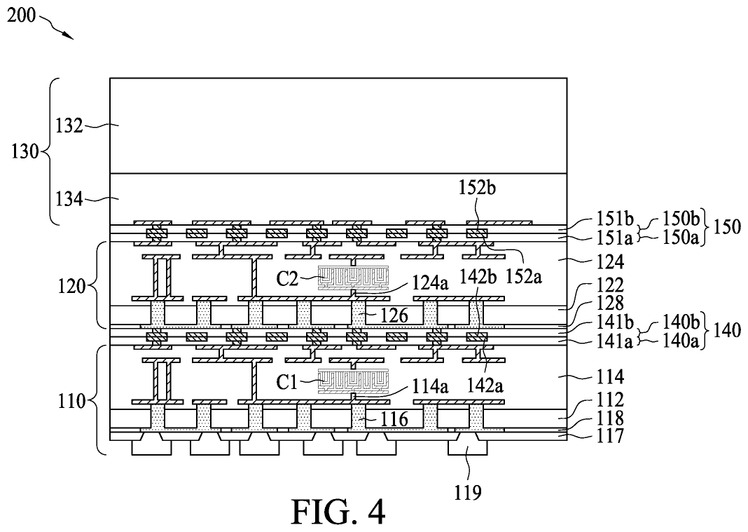

FIG. 4 shows a semiconductor structure 200 according to another embodiment of the present disclosure. The semiconductor structure 200 and the semiconductor structure 100 have similar structures, however, the difference between these two semiconductor structures 100 and 200 is in that, in the semiconductor structure 200, the chip 110 and the chip 120 are stacked with the front side of the chip 110 facing the back side of the chip 120, that is, the dielectric 114 of the chip 110 is in proximity to the semiconductive layer 122 of the chip 120.

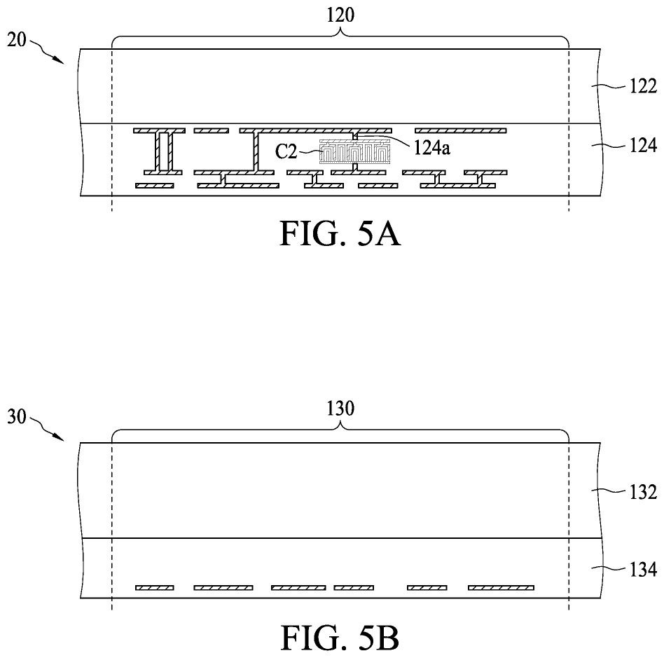

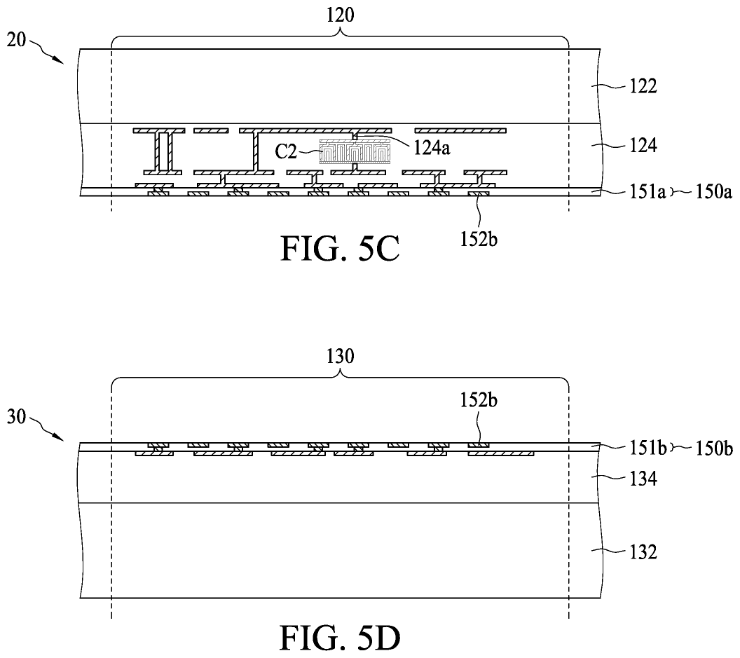

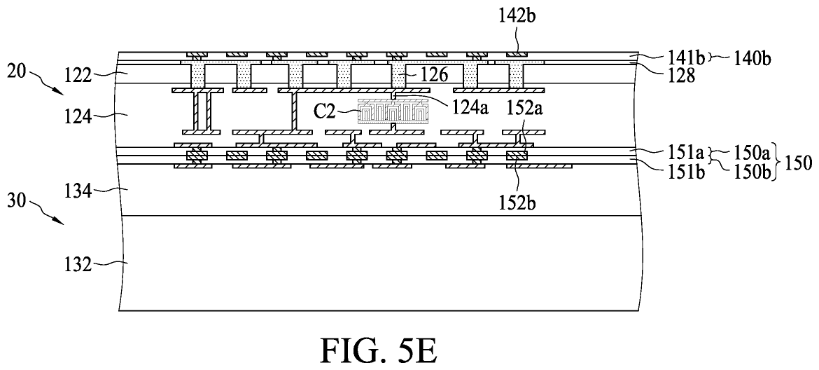

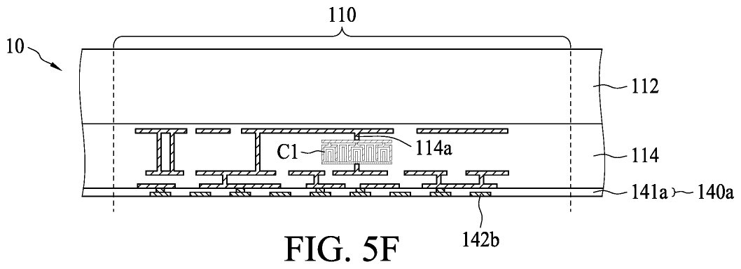

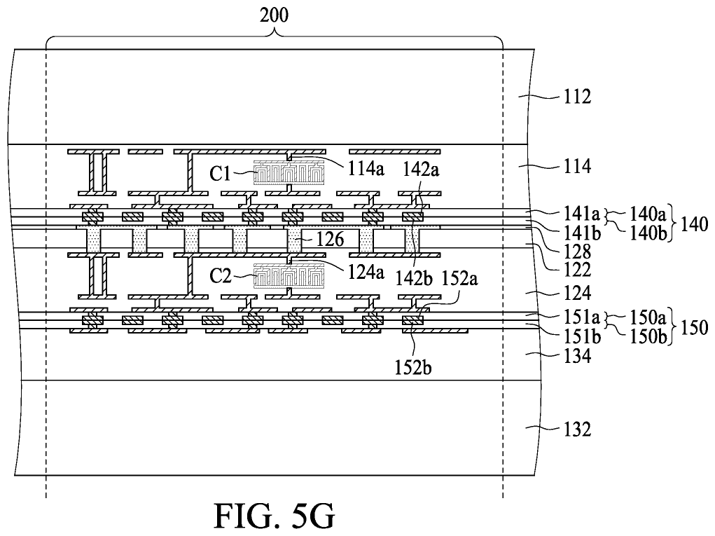

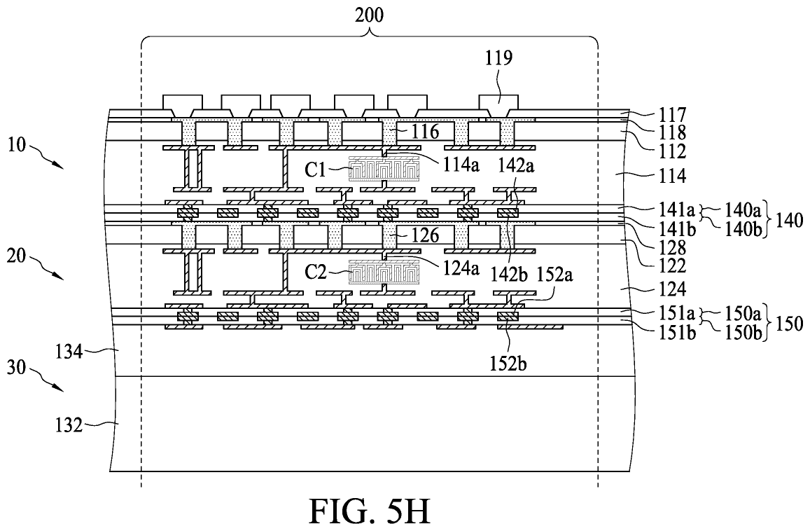

In some embodiments, the semiconductor structure 200 can also be manufactured by the method M1. However, the performing orders of steps S110 to S160 may not be the same as shown in FIG. 2. FIGS. 5A to 5H show cross-sectional views of one or more stages of the method M1 for manufacturing the semiconductor structure 200 according to one embodiment of the present disclosure.

As shown in FIGS. 5A and 5B, the steps S120 and S140 can be performed first to receive the wafer 20 and the power management wafer 30. Step S150 can be performed to bond the power management wafer 30 over the wafer 20. In some embodiments, the bonding layer 150 that bonds the power management wafer 30 and the wafer 20 can be formed by forming the sub-bonding layer 150a on the dielectric 124 of the wafer 20 as shown in FIG. 5C, forming the sub-bonding layer 150b on the dielectric 134 of the power management wafer 30 as shown in FIG. 5D, and bonding the sub-bonding layer 150a and the sub-bonding layer 150b as shown in FIG. 5E.

Furthermore, as shown in FIG. 5E, after the power management wafer 30 and the wafer 20 are bonded, the semiconductive layer 122 can be ground to be thinned down so that the via 126 can be formed therein. The RDL 128 can be formed on the semiconductive layer 122 and the via 126, and the sub-bonding layer 140b can be formed on the RDL 128.

Steps S110 and S130 are performed. As shown in FIG. 5F, the step S110 of receiving the wafer 10 is performed. In some embodiments, to form the bonding between the wafer 10 and the wafer 20, the sub-bonding layer 150a is further formed on the dielectric 114 of the wafer 10 as shown in FIG. 5F. As a result, the step S130 can be performed by bonding the sub-bonding layer 150a to the sub-bonding layer 150b as shown in FIG. 5G, and the stacked structure including the wafer 10, the wafer 20 and the power management wafer 30 is formed. Afterwards, the semiconductive layer 112 can be ground to be thinned down, the via 116 can be formed in the semiconductive layer 112, the RDL 118 can be formed on the semiconductive layer 112 and the via 116, and the conductive bumps 119 as well as the passivation layer 117 can be formed on the RDL 118 as shown in FIG. 5H. In step S160, die sawing process can be performed to saw the stacked wafers so that the semiconductor structure 200 can be singulated.

In the semiconductor structure 200, the chip 110 and the chip 120 are stacked with the front side of the chip 110 facing the back side of the chip 120, that is, the first dielectric 114 of the chip 110 is in proximity to the second semiconductive 122 of the chip 120. However, the present disclosure is not limited thereto. In some other embodiments, the chip 110 and the chip 120 can be stacked in a front-to-front manner or a back-to-back manner.

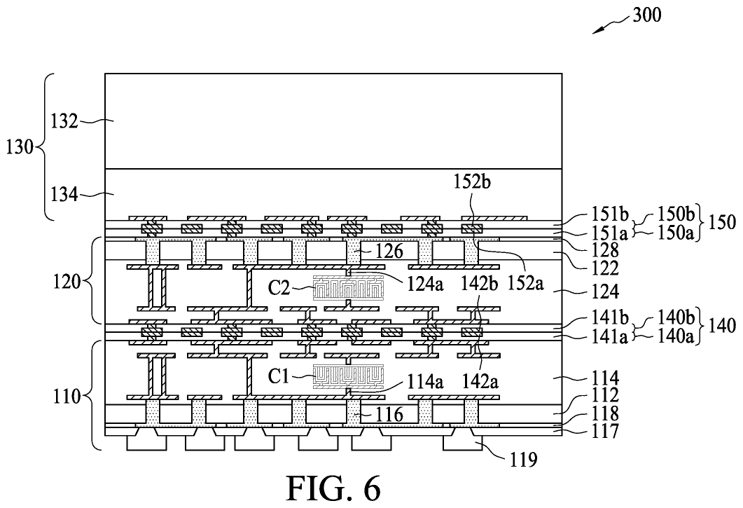

FIG. 6 shows a semiconductor structure 300 according to another embodiment of the present disclosure. The semiconductor structure 300 and the semiconductor structure 100 have similar structures, however, the difference between these two semiconductor structures 100 and 300 is in that, in the semiconductor structure 300, the chip 110 and the chip 120 are stacked with the front side of the chip 110 facing the front side of the chip 120, that is, the dielectric 114 of the chip 110 is in proximity to the dielectric 124 of the chip 120.

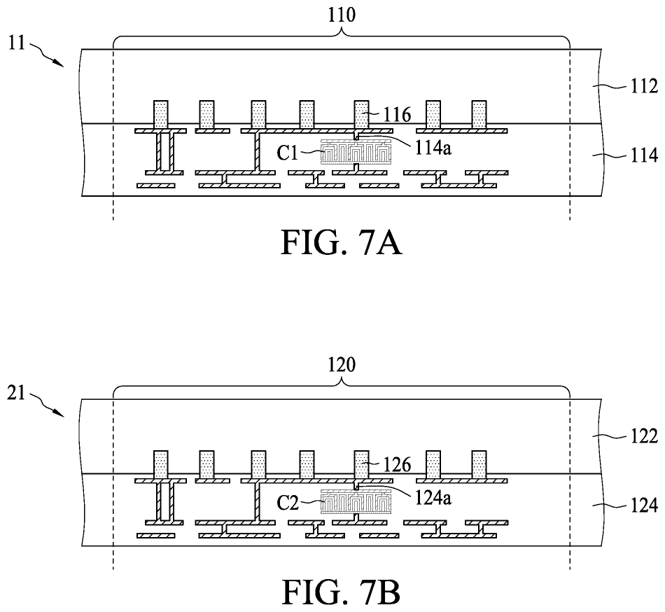

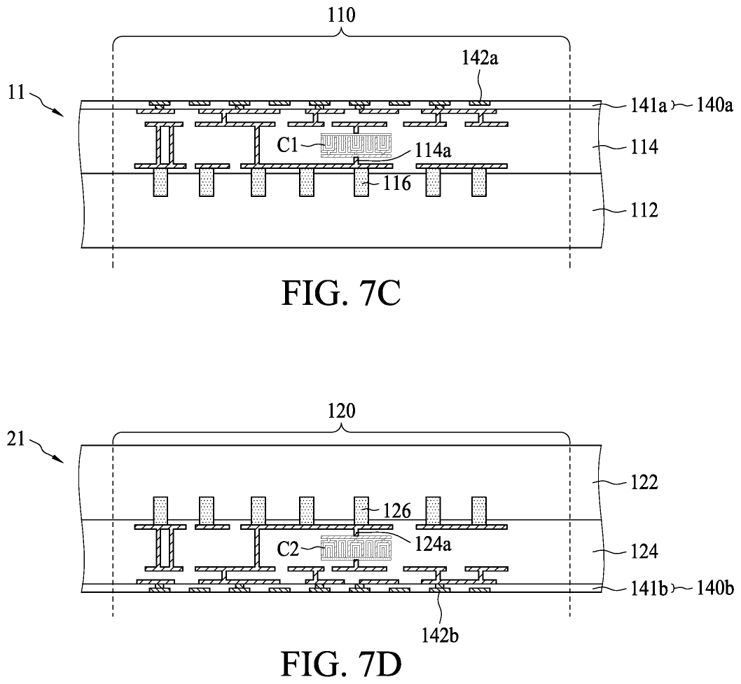

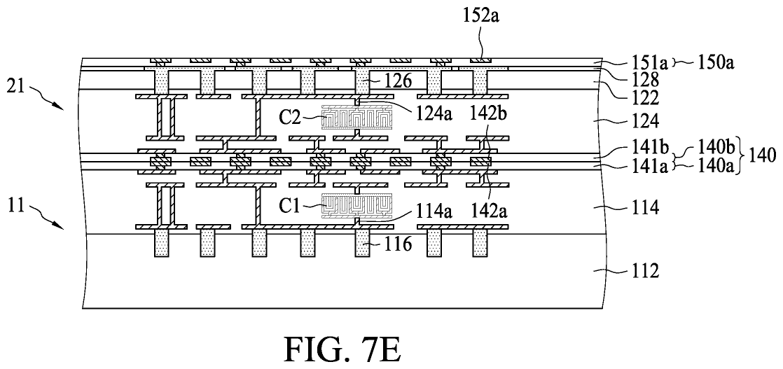

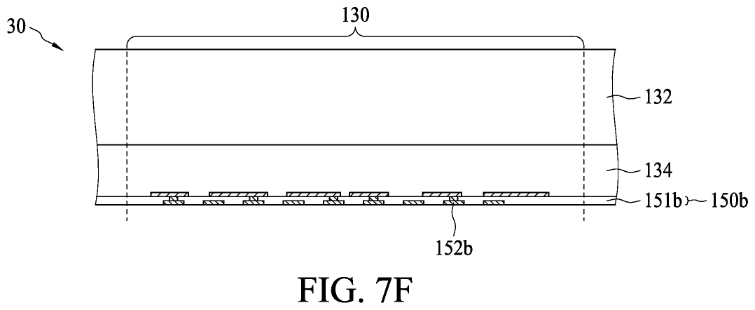

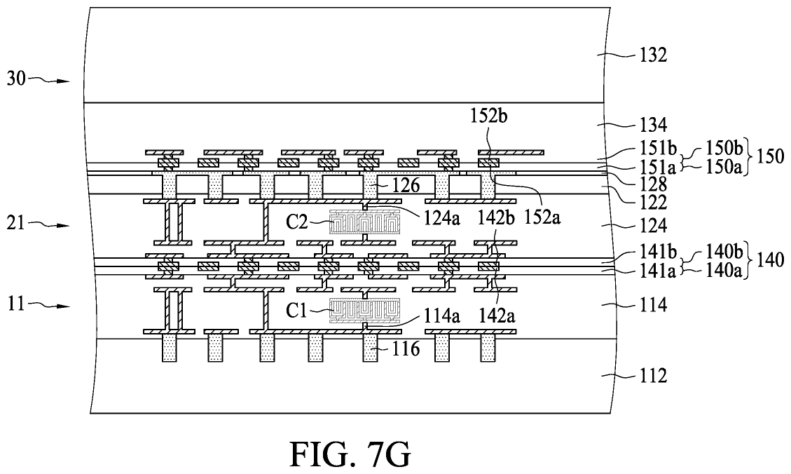

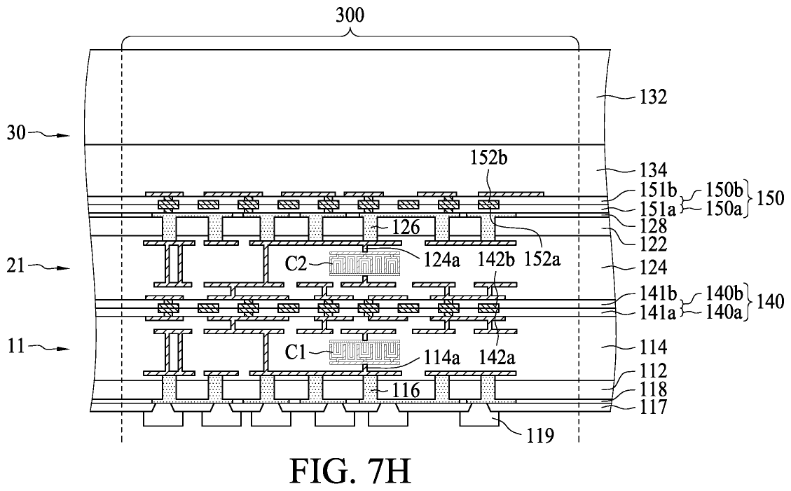

In some embodiments, the semiconductor structure 200 can also be manufactured by the method M1. FIGS. 7A to 7H show cross-sectional view of one or more stages of the method M1 for manufacturing the semiconductor structure 300 according to one embodiment of the present disclosure.

As shown in FIGS. 7A and 7B, the step S110 and S120 can be performed to receive the wafer 11 and the wafer 21. In some embodiments, the wafer 11 and the wafer 21 are similar to the wafer 10 and the wafer 20. However, in the wafer 11 and the wafer 21, the vias 116 and 126 are formed in a via middle (VM) manner. That is, the vias 116 and 126 can be formed after the front end of line (FEOL) process and before the back end of line (BEOL) process. Therefore, the vias 116 and 126 are already respectively formed in the semiconductive layers 112 and 122 of the wafer 11 and the wafer 21 before the stacking process.

Step S130 is performed to form the bonding between the wafer 11 and the wafer 21. In some embodiments, to form the bonding layer 140, the sub-bonding layer 140a can be formed on the dielectric 114 of the wafer 11 as shown in FIG. 7C, the sub-bonding layer 140b can be formed on the dielectric 124 of the wafer 21 as shown in FIG. 7D. Afterwards, a hybrid bonding process can be performed to bond the sub-bonding layer 140a and the sub-bonding layer 140b so as to form the bonding layer 140 as shown in FIG. 7E. In such case, the wafer 11 and the wafer 21 are stacked in a front-to-front manner, and the bonding layer 140 can contact the dielectric 114 and the dielectric 124.

Also, as shown in FIG. 7E, after the wafer 11 and the wafer 21 are bonded, the semiconductive layer 122 can be ground to expose the via 126 formed in the semiconductive layer 122, the RDL 128 can be formed on the semiconductive layer 122 and the via 126, and the sub-bonding layer 150a can be formed on the RDL 128.

The power management wafer 30 is received as shown in FIG. 7F when step S140 is performed. Furthermore, to facilitate the bonding between the power management wafer 30 and the wafer 21, the sub-bonding layer 150b is further formed on the dielectric 134 of the power management wafer 30 as shown in FIG. 7F.

Step S150 is performed so that the power management wafer 30 including a plurality of power management dies 130 can be bonded over the wafer 21 as shown in FIG. 7G. As a result, the stacked structure including the wafer 11, the wafer 21, and the power management wafer 30 is formed. Afterwards, the semiconductive layer 112 of the wafer 11 is ground to expose the via 116, the RDL 118 is formed on the semiconductive layer 112 and the via 116, and the conductive bumps 119 as well as the passivation layer 117 are formed on the RDL 118 as shown in FIG. 7H. In step S160, die sawing process can be performed to dice the stacking wafers so that the semiconductor structure 300 can be singulated.

Although each of the semiconductor structures 100, 200, and 300 includes two capacitor chips, the present disclosure is not limited thereto. In some embodiments, more capacitor chips can be stacked in the semiconductor structure so as to further improve the power efficiency of the voltage conversion performed by the PMIC.

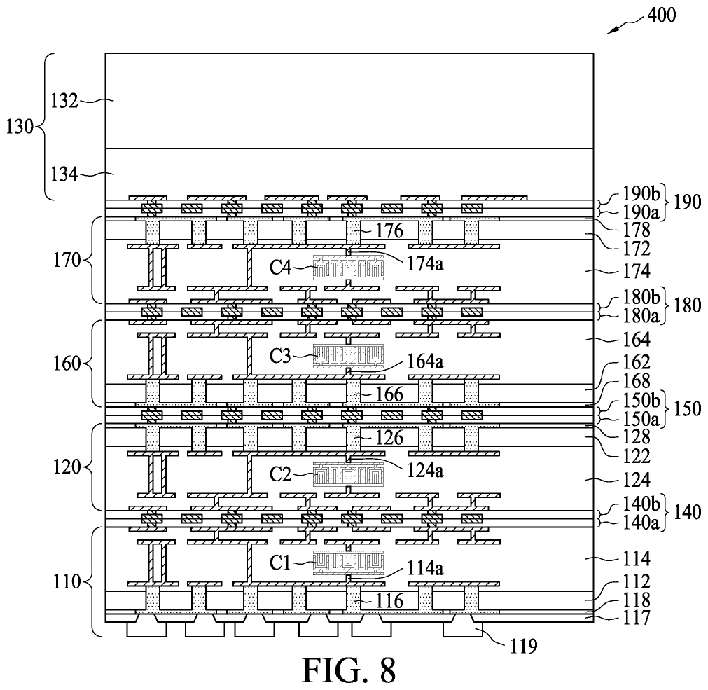

FIG. 8 shows a semiconductor structure 400 according to another embodiment of the present disclosure. The semiconductor structure 400 and the semiconductor structure 300 have similar structures, however, the difference between these two semiconductor structures 300 and 400 is in that the semiconductor structure 400 includes more stacked chips. As shown in FIG. 8, in addition to the chip 110 and the chip 120, the semiconductor structure 400 further includes chips 160 and 170.

In some embodiments, the chip 110, the chip 120, the chip 160, and the chip 170 can have the same structure. For example, the chip 160 includes a dielectric 164, and a semiconductive layer 162 over the dielectric 164. Also, at least one 3D capacitor structure C3 and at least one interconnect structure 164a are formed in the dielectric 164. Similarly, the chip 170 includes a dielectric 174, and a semiconductive layer 172 over the dielectric 174. Also, at least one 3D capacitor structure C4 and at least one interconnect structure 174a are formed in the dielectric 174.

Furthermore, the chip 120 can be bonded to the chip 160 with a bonding layer 150 formed by bonding a sub-bonding layer 150a formed on the chip 120 to a sub-bonding layer 150b formed on the chip 160. The chip 160 can be bonded to the chip 170 with a bonding layer 180 formed by bonding a sub-bonding layer 180a formed on the chip 160 to a sub-bonding layer 180b formed on the chip 170. In addition, the chip 170 can be bonded to the power management die 130 with a bonding layer 190 formed by bonding a sub-bonding layer 190a formed on the chip 160 to a sub-bonding layer 190b formed on the power management die 130. It may be noted that in the semiconductor structure 400, different chips can be stacked in a front-to-front manner or a back-to-back manner. For example, the chip 110 and the chip 120 can be bonded in a front-to-front manner, and the chip 120 and the chip 160 can be bonded in a back-to-back manner. That is, the first dielectric 114 of the chip 110 is in proximity to the dielectric 124 of the chip 120, and the semiconductive layer 122 of the chip 120 is in proximity to the semiconductive layer 162 of the chip 160. In some embodiments, the capacitor chips can be stacked in a manner of front-to-back, front-to-front, or back-to-back depending on the requirements.

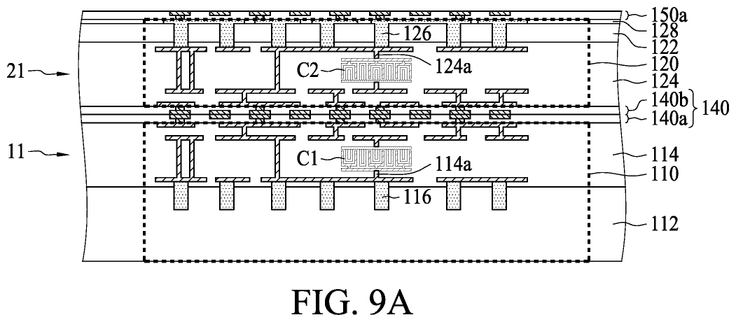

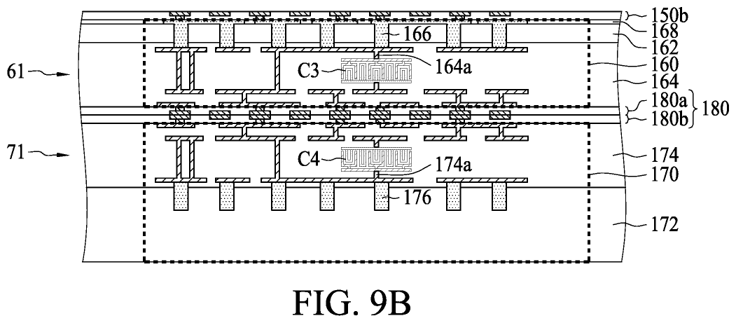

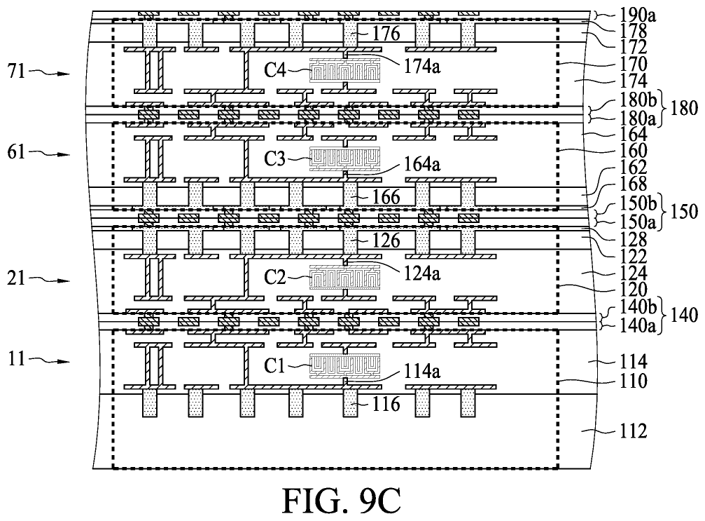

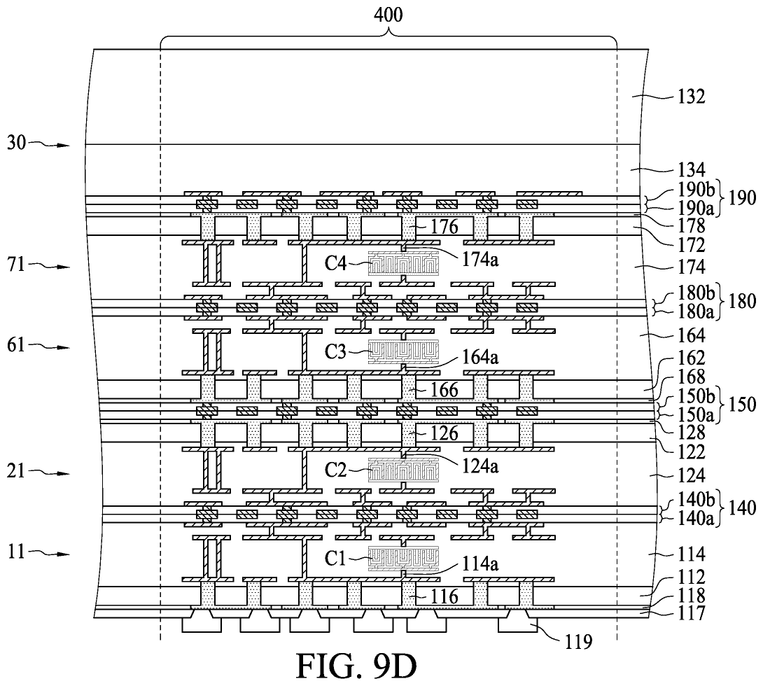

In some embodiments, the semiconductor structure 400 can also be manufactured by the method M1 by repeating some of the steps. FIGS. 9A to 9D show cross-sectional view of one or more stages of the method M1 for manufacturing the semiconductor structure 400 according to one embodiment of the present disclosure.

As shown in FIG. 9A, steps S110 to S130 can be performed so that the wafer 11 and the wafer 21 can be bonded. In some embodiments, the processes shown in FIGS. 7A to 7D can be adopted to form the structure shown in FIG. 9A. As a result, the semiconductive layer 122 is grinded to be thinner so as to expose the via 126. The RDL 128 is formed on the semiconductive layer 122 and the via 126, and the sub-bonding layer 150a is formed on the RDL 128.

Steps S110 to S120 can be repeated again for receiving the wafer 61 with a plurality of chips 160 formed therein and the wafer 71 with a plurality of chips 170 formed therein. The step S130 can also be repeated for bonding the wafer 61 and the wafer 71 as shown in FIG. 9B. In some embodiments, after the wafer 71 and the wafer 61 are bonded, the semiconductive layer 162 is ground to be thinner so as to expose the via 166. The RDL 168 is formed on the semiconductive layer 162 and the via 166, and the sub-bonding layer 150b is formed on the RDL 168. Afterwards, the wafer 61 can be further bonded to the wafer 21 with the bonding layer 150 formed by bonding the sub-bonding layers 150a and 150b. As a result, the four wafers 11, 21, 61, and 71 can be stacked as shown in FIG. 9C.

After the four wafers 11, 21, 61, and 71 are stacked, steps S140 and S150 can be performed. For example, the power management wafer 130 can be bonded to the fourth wafer 170 through the bonding layer 190 formed by bonding the sub-bonding layers 190a and 190b as shown in FIG. 9D. Furthermore, as shown in FIG. 9D the semiconductive layer 112 of the wafer 110 can be ground to expose the via 116, the RDL 118 can be formed on the semiconductive layer 112 and the via 116, and the conductive bumps 119 as well as the passivation layer 117 can be formed on the RDL 118. In step S160, die sawing process can be performed to dice the stacking wafers so that the semiconductor structure 400 can be singulated.

In the processes shown in FIGS. 3A to 3H and FIGS. 5A to 5H, the wafer 10 and the wafer 20 can have the same structures that have no via formed in the semiconductive layers upon receipt, that is, the vias are formed during the process of wafer stacking (i.e., via last). Also, in the processes shown in FIGS. 7A to 7H and FIGS. 9A to 9C, the wafer 11, the wafer 21, the wafer 61, and the wafer 71 can have the same structures that have vias formed in the semiconductive layers upon receipt (i.e., via middle). However, the present disclosure is not limited thereto. In some embodiments, the semiconductor structures 100 to 400 can be manufactured by wafers having different structures.

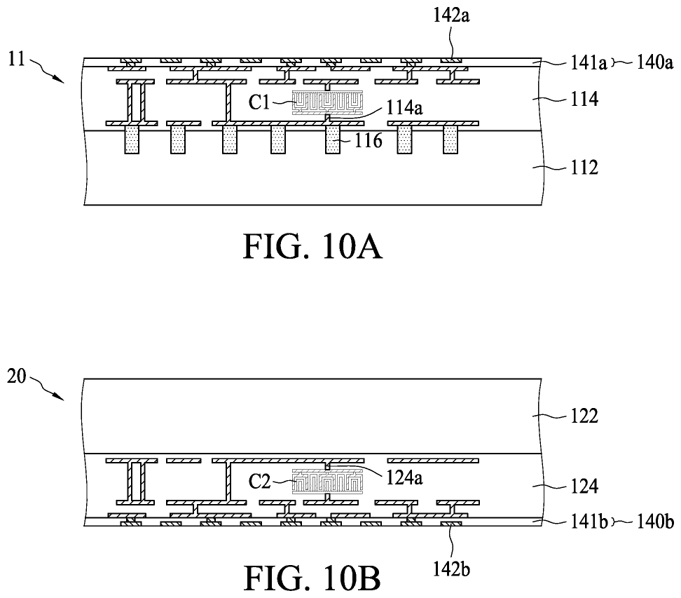

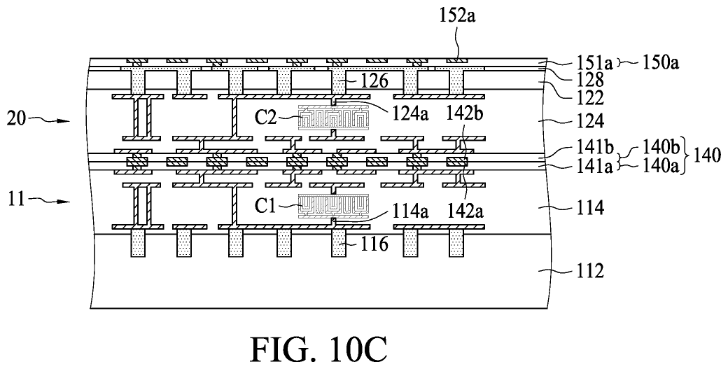

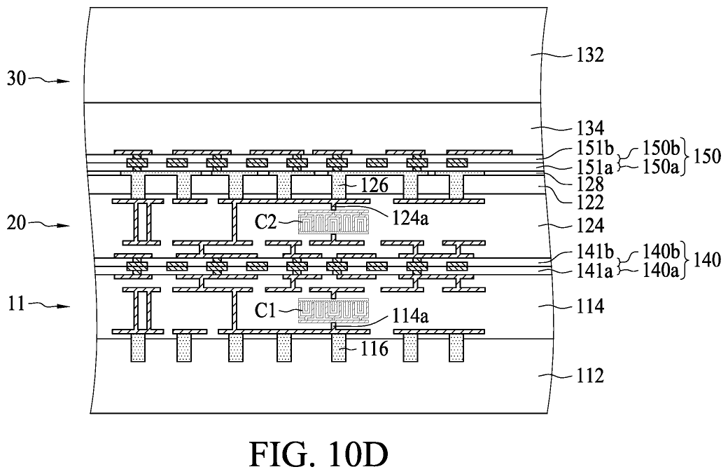

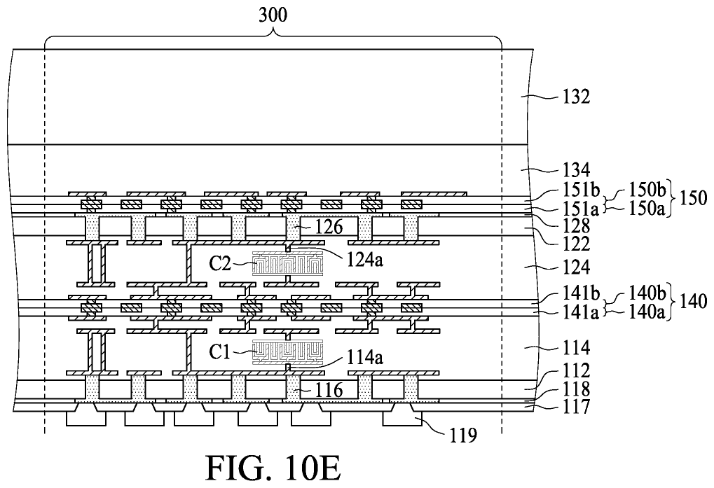

FIGS. 10A to 10E show cross-sectional view of one or more stages of the method M1 for manufacturing the semiconductor structure 100 according to one embodiment of the present disclosure.

In step S110, the wafer 11 that have vias 116 formed in the semiconductive layer 112 is provided as shown in FIG. 10A, and in step S120, the wafer 20 that have no via formed in the semiconductive layer 122 is provided as shown in FIG. 10B. Furthermore, as shown in FIGS. 10A and 10B, the sub-bonding layer 140a is formed on the dielectric 114, and the sub-bonding layer 140b is formed on the second dielectric 124. In such case, step S130 can be performed to form the bonding layer 140 by bonding the sub-bonding layer 140a and the sub-bonding layer 140b through a hybrid bonding process. As a result, the wafer 11 and the wafer 20 can be bonded as shown in FIG. 10C.

Furthermore, as shown in FIG. 10C, the semiconductive layer 122 is ground to expose the via 126, and the RDL 128 is formed on the semiconductive layer 122 and the via 126. In addition, the sub-bonding layer 150a is further formed on the RDL 128. In such case, when the power management wafer 30 is received in step S140, the sub-bonding layer 150b can be formed on the power management wafer 30 so that, in step S150, the power management wafer 30 can be bonded to the wafer 20 through the bonding layer 150 formed by bonding the sub-bonding layer 150a and the sub-bonding layer 150b as shown in FIG. 10D.

After the stacked structure of the wafer 11, the wafer 20, and the power management wafer 30 is formed, the semiconductive layer 112 of the wafer 11 is ground to expose the via 116, the RDL 118 is formed on the semiconductive layer 112 and the via 116, and the conductive bumps 119 as well as the passivation layer 117 are formed on the RDL 118 as shown in FIG. 10E. In step S160, a sawing process can be performed to dice the stacking wafers so that the semiconductor structure 300 can be singulated.

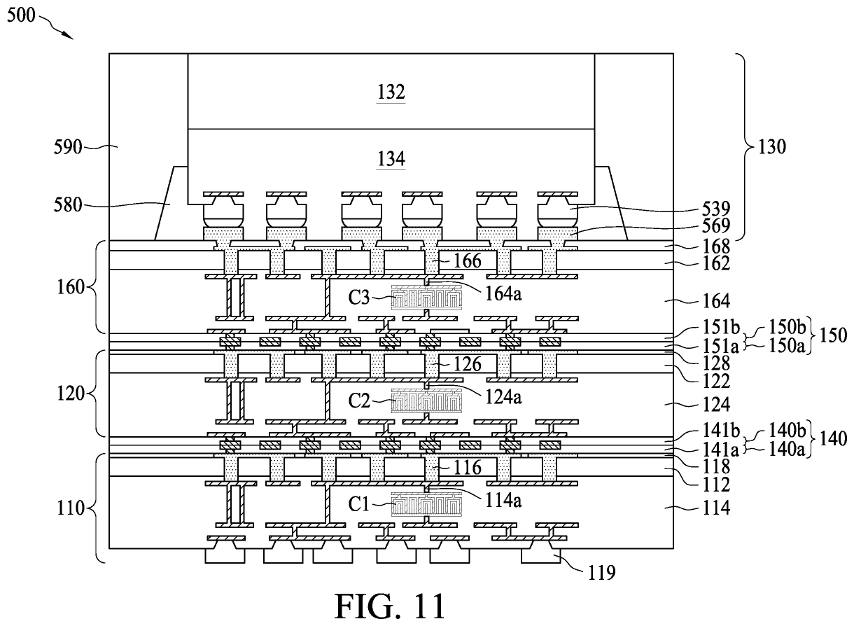

In some embodiments, in the semiconductor structures 100, 200, 300, or 400, the power management die 130 is bonded to the capacitor chip in a wafer on wafer (WoW) manner, however, the present disclosure is not limited thereto. FIG. 11 shows a semiconductor structure 500 according to one embodiment of the present disclosure.

The semiconductor structure 500 and the semiconductor structure 100 have similar structures. However, the semiconductor structure 500 includes three capacitor chips 110, 120, and 160, and the power management die 130 is bonded to the capacitor chip 160 through conductive bumps 539 and bump pads 569. That is, the power management die 130 is stacked on the capacitor chips 160 in a chip on wafer (CoW) manner.

As shown in FIG. 11, the semiconductor structure 500 includes the chips 110, 120, 160, and the power management die 130. The chip 110 can be boned to the chip 120 through the bonding layer 140, and the chip 120 can be bonded to the chip 160 through the bonding layer 150. Furthermore, the semiconductor structure 500 further includes a plurality of bump pads 569 formed on the RDL 168 of the chip 160, and a plurality of conductive bumps 539 formed on the dielectric 134 of the power management die 130. In some embodiments, the conductive bumps 539 can be micro bumps that are aligned correspondingly with the bump pads 569 so that the power management die 130 can be bonded to the chip 160 by bonding the conductive bumps 539 to the bump pads 569. In addition, the semiconductor structure 500 further includes an underfill 580 surrounding the conductive bumps 539 and is disposed over the chip 160 so as to protect the bonding between the conductive bumps 539 and the bump pads 569. In some embodiments, to further protect the semiconductor structure 500, a molding layer 590 is disposed on the chip 160 and surrounding the power management die 130, the underfill 580 and the conductive bumps 539. However, the present disclosure is not limited thereto. In some other embodiments, the underfill 580 and the molding layer 590 can be replaced by adopting a molded underfill (MUF) layer that can fill the gaps between the conductive bumps 539 and mold the power management die 130 at the same time.

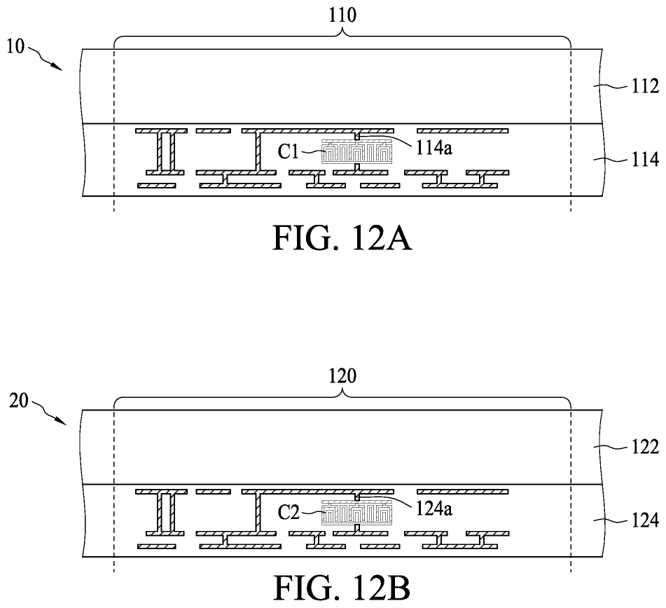

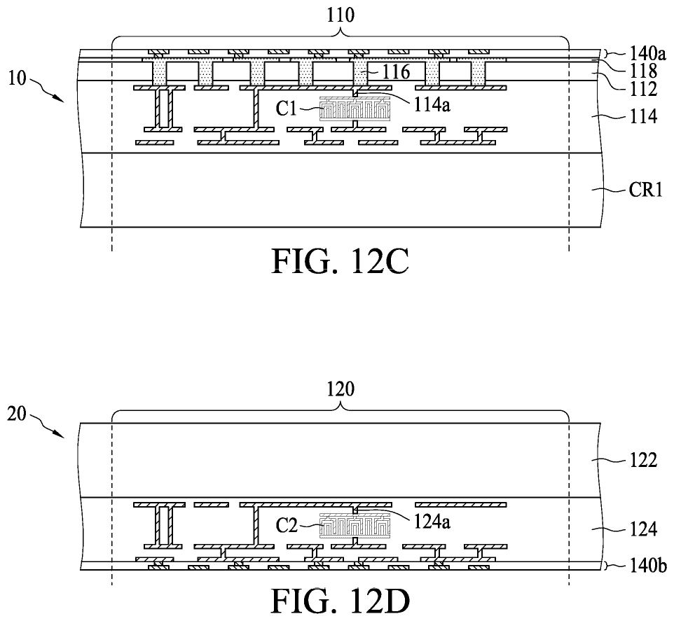

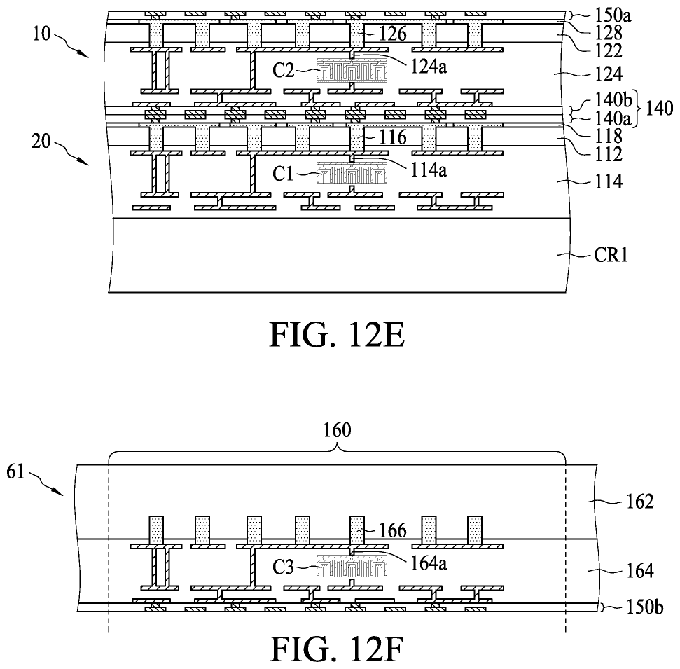

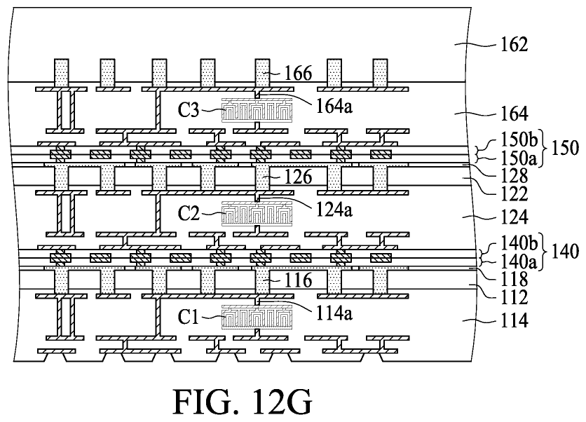

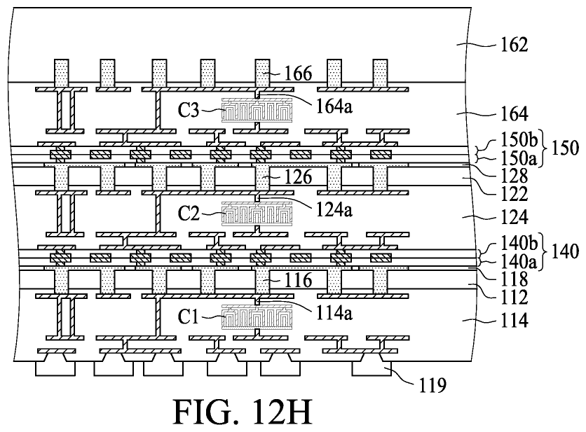

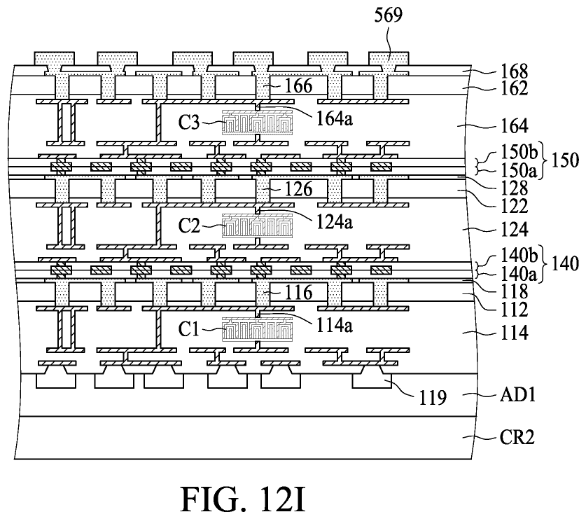

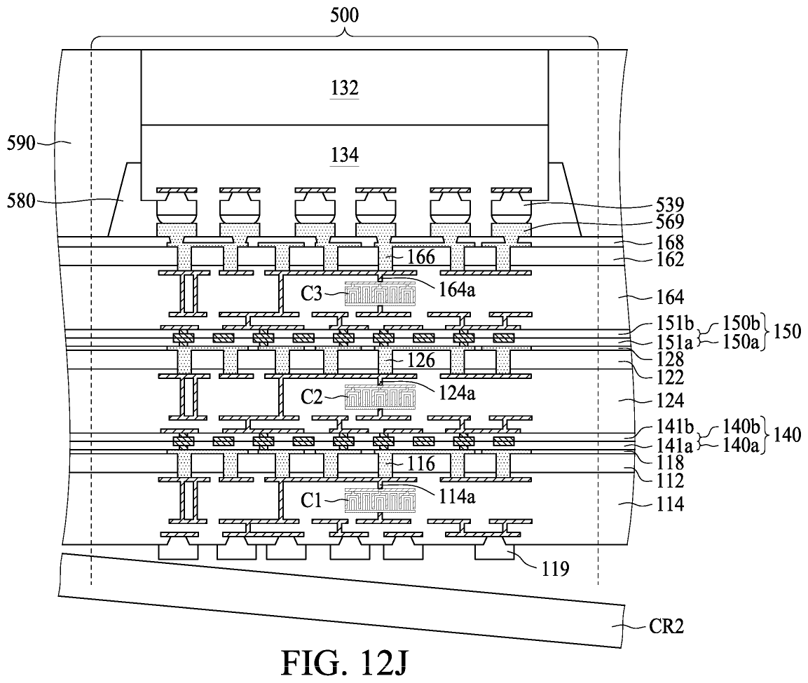

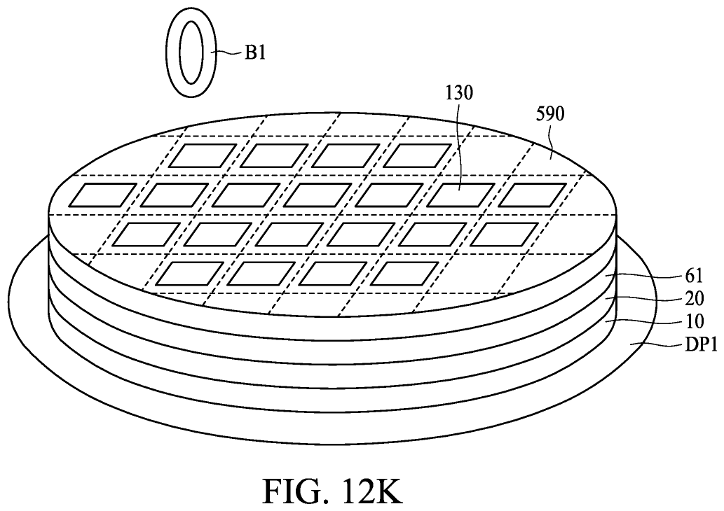

FIGS. 12A to 12K show cross-sectional view of one or more stages for manufacturing the semiconductor structure 500 according to one embodiment of the present disclosure. As shown in FIGS. 12A and 12B, the wafer 10 and the wafer 20 are received. In some embodiments, a plurality of chips 110 are formed in the wafer 10, and a plurality of chips 120 are formed in the wafer 20. In some embodiments, the wafer 10 and the wafer 20 can have the same structures and can be replicas.

Furthermore, to facilitate the bonding between the wafer 10 and the wafer 20, the sub-bonding layer 140a and the sub-bonding layer 140b are formed on the wafers 10 and 20 respectively. In some embodiments, the carrier CR1 is temporarily attached to the dielectric 114 of the wafer 10 so that the via 116 can be formed in the semiconductive layer 112 with enough supporting strength. The RDL 118 can be formed on the via 116 and the semiconductive layer 112, and the sub-bonding layer 140a can be formed on the RDL 118 as shown in FIG. 12C. In addition, as shown in FIG. 12D, the sub-bonding layer 140b can be formed on the dielectric 124 of the wafer 20 without using carriers.

As a result, the sub-bonding layer 140a and the sub-bonding layer 140b can be bonded by a hybrid bonding process so that the wafer 10 can be bonded to the wafer 20 as shown in FIG. 12E. In addition, as shown in FIG. 12E, after the wafer 20 is bonded to the wafer 10, the via 126 can be formed in the semiconductive layer 122 of the wafer 20, the RDL 128 can be formed on the via 126 and the semiconductive layer 122, and the sub-bonding layer 150a can be formed on the RDL 128 so as to facilitate the bonding with the next chip.

In FIG. 12F, another wafer 61 including a plurality of chips 160 is received. Also, to bond the wafer 61 to the wafer 20, the sub-bonding layer 150b is formed on the dielectric 164 of the wafer 61. As a result, the sub-bonding layer 150a and the sub-bonding layer 150b can be bonded by a hybrid bonding process so that the wafer 61 can be bonded to the wafer 20 as shown in FIG. 12G.

After the wafer 61 is bonded to the wafer 20, the carrier CR1 can be removed, and openings can be formed on the surface of the dielectric 114 so that the conductive bumps 119 can be formed on the dielectric 114 and coupled to the interconnect structure 114a of the dielectric 114 as shown in FIG. 12H. An adhesive layer AD1 can be applied to the wafer 10 so as to protect the conductive bumps 119 and adhere a carrier CR2 to the stacked structure. In such case, the carrier CR2 is able to provide the supporting strength for the following processes, including grinding the semiconductive layer 162 to expose the via 166 therein, forming the RDL 168 on the semiconductive layer 162 and the via 166, and forming the bump pads 569 on the RDL 168. In some embodiments, the carrier CR2 can be a glass substrate.

In addition, a plurality of power management dies 130 can be received, and the plurality of conductive bumps 539 can be formed on the dielectric 134 of the power management dies 130. The power management dies 130 can be bonded over the wafer 61 by bonding the conductive bumps 539 to the bump pads 569 formed on the wafer 61 as shown in FIG. 12J. Furthermore, in some embodiments, after the power management dies 130 are bonded to the wafer 61, the underfill 580 can be applied to protect the connection between the conductive bumps 539 to the bump pads 569, and a molding process can be performed to mold the power management dies 130 on the wafer 61 with the molding layer 590. The carrier CR2 can be removed, and die sawing process can be performed to singulate the semiconductor structure 500 from the CoW structure as shown in FIG. 12K. In some embodiments, the wafer 10 can be attached to a dicing tape DP1, and the blade B1 can cut the stacked structure from the molding layer 590 surrounding the power management die 130. However, the present disclosure is not limited thereto. In some other embodiments, the molding layer 590 and the back sides of the power management dies 130 can be attached to the dicing tape DP1, and the blade B1 can cut the stacked structure from the surface of the wafer 10.

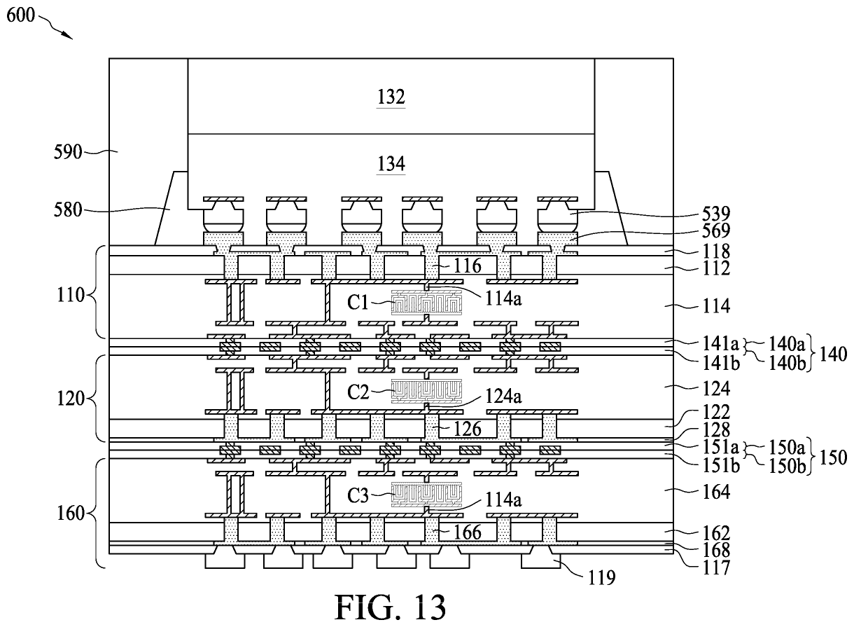

FIG. 13 shows a semiconductor structure 600 according to one embodiment of the present disclosure. The semiconductor structure 600 and the semiconductor structure 500 have similar structures. However, while the chips 110, 120, and 160 are all stacked in a front-to-back manner in the semiconductor structure 500, the chips 110, 120, and 160 can be stacked in different manners in the semiconductor structure 600, for example, the chip 120 can be stacked on the chip 110 in the front-to-front manner while the chip 160 can be stacked on the chip 120 in the front-to-back manners.

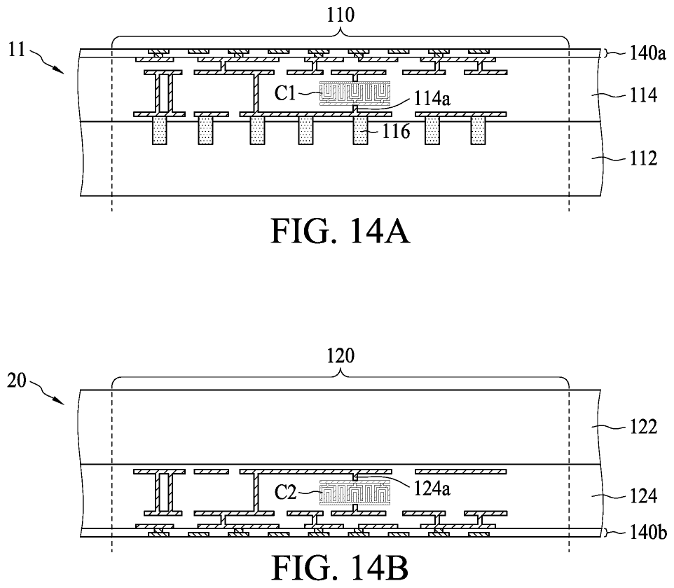

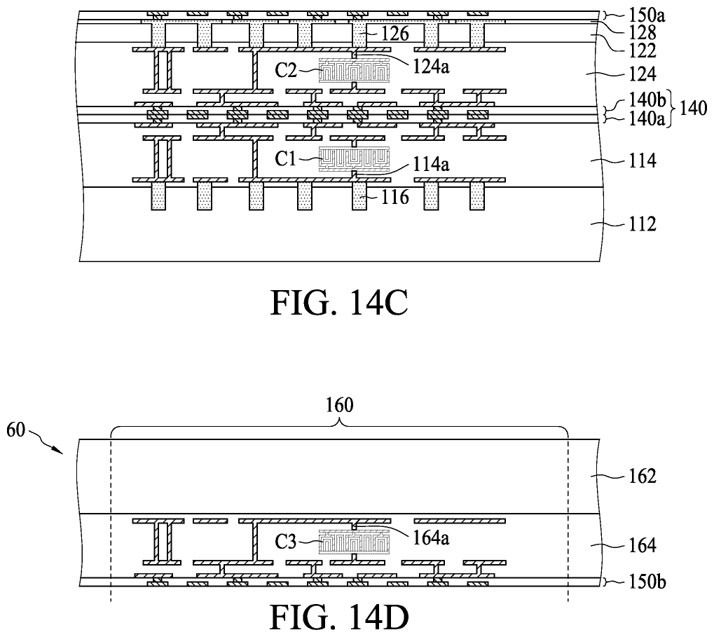

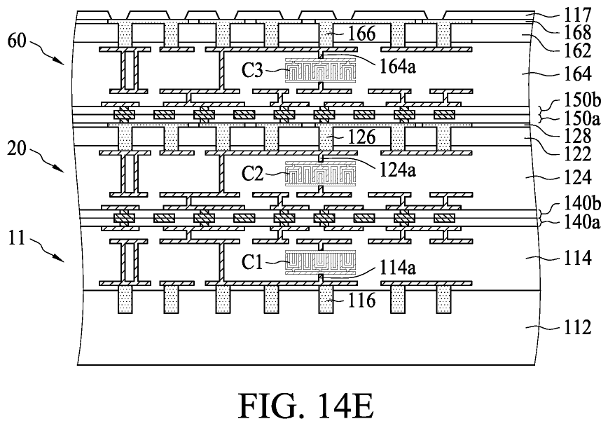

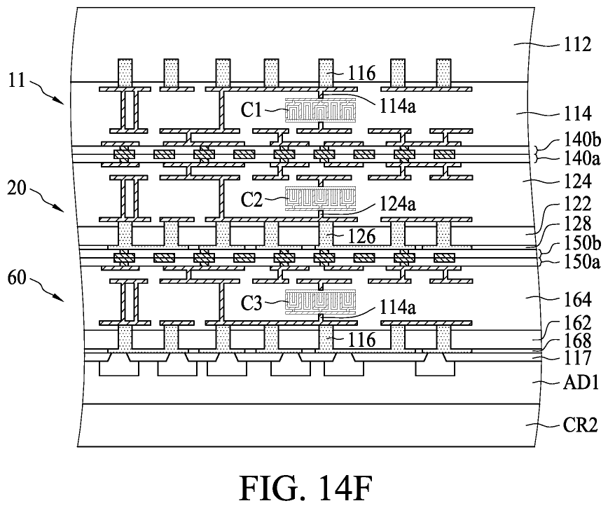

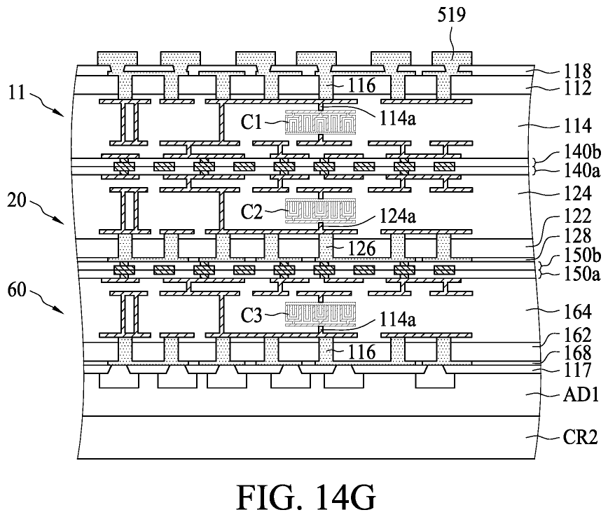

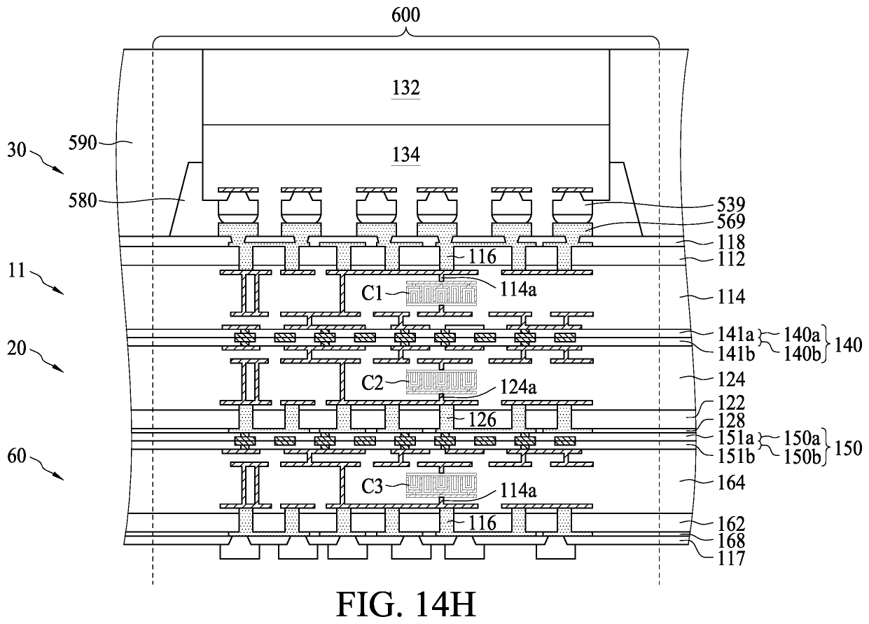

FIGS. 14A to 14H show cross-sectional view of one or more stages for manufacturing the semiconductor structure 600 according to one embodiment of the present disclosure. As shown in FIGS. 14A and 14B, the wafers 11 and 20 are received. In some embodiments, the wafer 11 may be different from the wafer 20 in that the wafer 11 has via formed in the semiconductive layer 112 while the wafer 20 does not.

Furthermore, to facilitate the bonding between the wafer 11 and the wafer 20, the sub-bonding layer 140a and the sub-bonding layer 140b are formed on the dielectrics 114 and 124 of the wafers 11 and 20 respectively. As a result, the sub-bonding layer 140a and the sub-bonding layer 140b can be bonded by a hybrid bonding process so that the wafer 11 can be bonded to the wafer 20 as shown in FIG. 14C. In addition, as shown in FIG. 14C, after the wafer 20 is bonded to the wafer 11, the via 126 can be formed in the semiconductive layer 122 of the wafer 20, the RDL 128 can be formed on the via 126 and the semiconductive layer 122, and the sub-bonding layer 150a can be formed on the RDL 128 so as to facilitate the bonding with the next chip.

In FIG. 14D, another wafer 60 is received. Also, to bond the wafer 60 to the wafer 20, the sub-bonding layer 150b is formed on the dielectric 164 of the wafer 61. As a result, the sub-bonding layer 150a and the sub-bonding layer 150b can be bonded by a hybrid bonding process so that the wafer 60 can be bonded to the wafer 20 as shown in FIG. 14E.

After the wafer 60 is bonded to the wafer 20, the semiconductive layer 162 can be ground to be thinner so as to form the via 166 in the semiconductive layer 162. The RDL 168 can be formed on the semiconductive layer 162 and the via 166, and then, the passivation layer 117 can be formed on the RDL 168 with openings for receiving the conductive bumps 119 later.

As shown in FIG. 14F, after the conductive bumps 119 is formed, the adhesive layer AD1 can be applied to the wafer 60 so as to protect the conductive bumps 119 and adhere a carrier CR2 to the wafer stacking structure. In such case, the carrier CR2 is able to provide the supporting strength for the following processes, including grinding the semiconductive layer 112 to expose the via 116 therein, forming the RDL 118 on the semiconductive layer 112 and the via 116, and forming the bump pads 519 on the RDL 118 as shown in FIG. 14G.

A plurality of power management dies 130 can be received, and the plurality of conductive bumps 539 can be formed on the dielectric 134 of each power management die 130. In such case, the power management dies 130 can be bonded over the wafer 60 by bonding the conductive bumps 539 to the bump pads 519 formed on the wafer 11 as shown in FIG. 14H. Furthermore, in some embodiments, after the power management dies 130 are bonded to the wafer 11, the underfill 580 can be applied to protect the connection between the conductive bumps 539 to the bump pads 519, and a molding process can be performed to mold the power management dies 130 on the wafer 11 with the molding layer 590. The carrier CR2 can be removed, and a sawing process can be performed to singulate the semiconductor structure 600 from the CoW structure.

In the processes shown in FIGS. 14A to 14H, the semiconductor structure 600 is manufactured by wafers having different structures, for example, the wafer 11 with via middle and the wafer 20 with via last are both adopted. However, the present disclosure is not limited thereto. In some embodiments, the semiconductor structure 600 can be manufactured by wafers of the same structures.

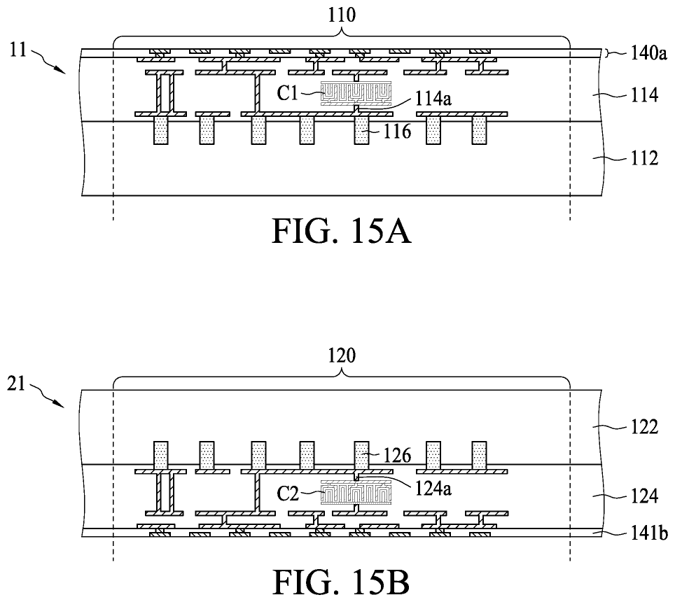

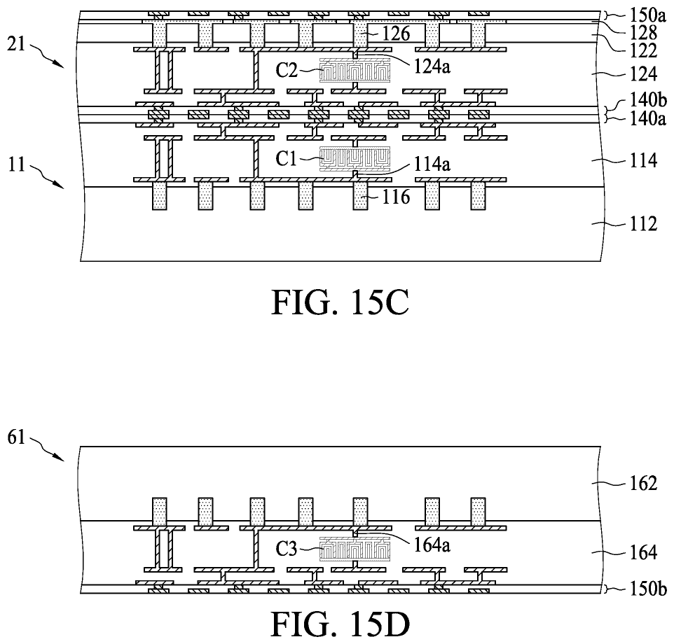

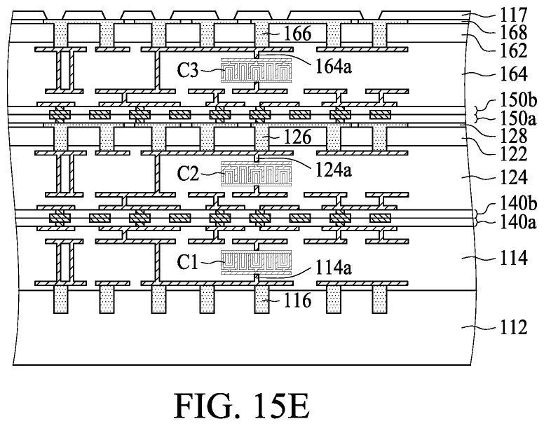

FIGS. 15A to 15E show cross-sectional view of one or more stages for manufacturing the semiconductor structure 600 according to another embodiment of the present disclosure. As shown in FIGS. 15A and 15B, the wafer 11 with a plurality of chips 110 formed therein and the wafer 21 with a plurality of chips 120 formed therein are received. In some embodiments, the wafer 11 and the wafer 21 can have the same structure that each has vias formed in the semiconductive layers 112 and 122 before the BEOL process.

Furthermore, to facilitate the bonding between the wafer 11 and the wafer 21, the sub-bonding layer 140a and the sub-bonding layer 140b are formed on the dielectrics 114 and 124 of the wafers 11 and 21 respectively. As a result, the sub-bonding layer 140a and the sub-bonding layer 140b can be bonded by a hybrid bonding process so that the wafer 11 can be bonded to the wafer 21 as shown in FIG. 15C. In addition, as shown in FIG. 15C, after the wafer 21 is bonded to the wafer 11, the semiconductive layer 122 of the wafer 21 can be ground to expose the via 126, the RDL 128 can be formed on the via 126 and the semiconductive layer 122, and the sub-bonding layer 150a can be formed on the RDL 128 so as to facilitate the bonding with the next chip.

In FIG. 15D, the wafer 61 with a plurality of chips 160 formed therein is received. In some embodiments, the wafer 61 can have the same structure as the wafer 11 and 21. Also, to bond the wafer 61 to the wafer 21, the sub-bonding layer 150b is formed on the dielectric 164 of the wafer 61. As a result, the sub-bonding layer 150a and the sub-bonding layer 150b can be bonded by a hybrid bonding process so that the wafer 61 can be bonded to the wafer 21 as shown in FIG. 15E

After the wafer 61 is bonded to the wafer 21, the semiconductive layer 162 can be ground to be thinner so as to expose the via 166 formed in the semiconductive layer 162. The RDL 168 can be formed on the semiconductive layer 162 and the via 166, and then, the passivation layer 117 can be formed on the RDL 168 with openings for receiving the conductive bumps 119 later. As a result, the structure shown in FIG. 15E becomes the same as the structure shown in FIG. 14E. Therefore, the following processes can also be referred to FIGS. 14F to 14H, and the redundant drawings are omitted for brevity. After the CoW structure that includes a plurality of semiconductor structures 600 is formed as shown in FIG. 14H, a sawing process can be performed to singulate the semiconductor structure 600.

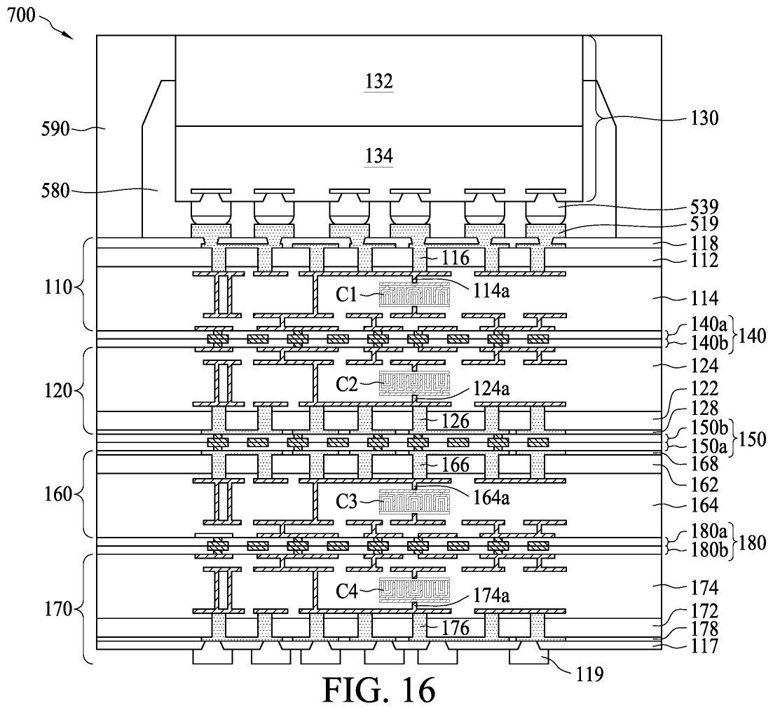

In some embodiments, the semiconductor structure can include more capacitor chips so as to improve the power efficiency of voltage conversion. FIG. 16 shows a semiconductor structure 700 according to one embodiment of the present disclosure. As shown in FIG. 16, the semiconductor structure 700 includes chips 110, 120, 160, 170, and a power management die 130.

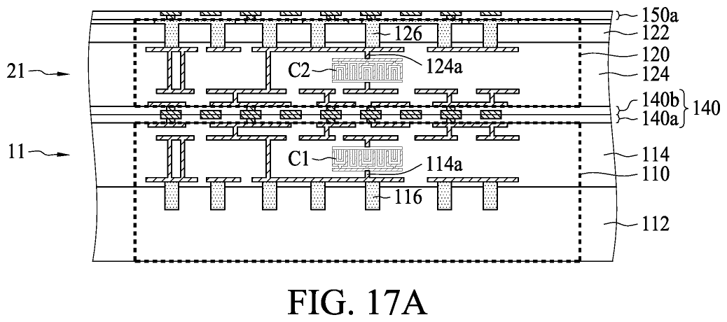

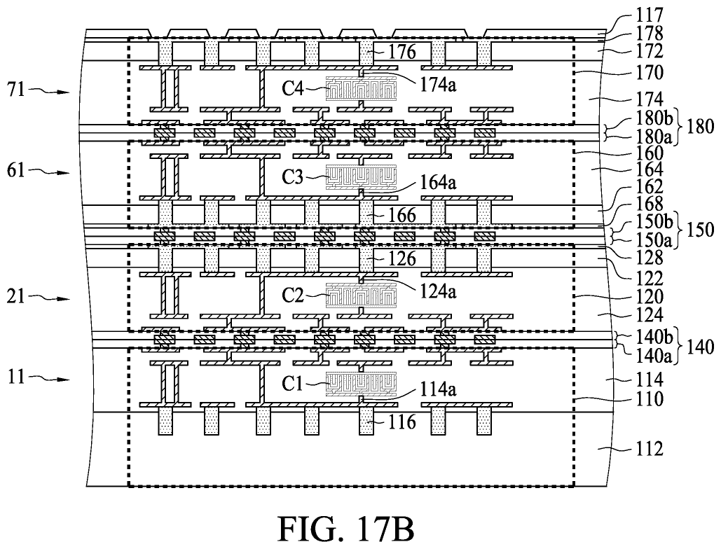

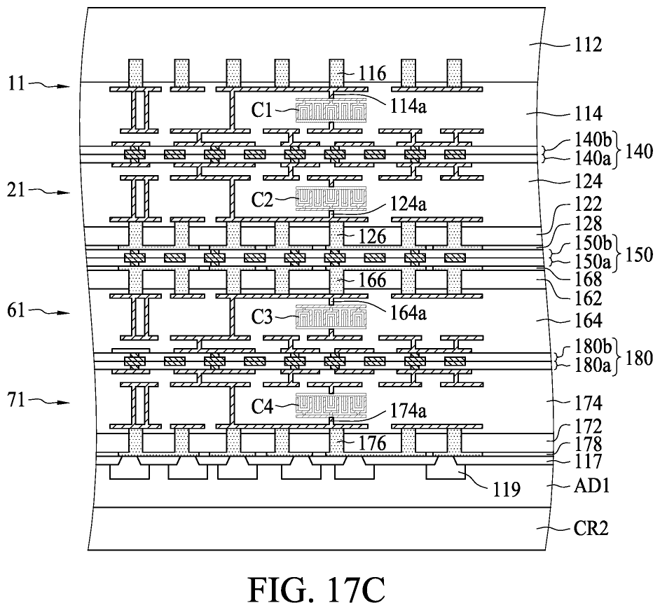

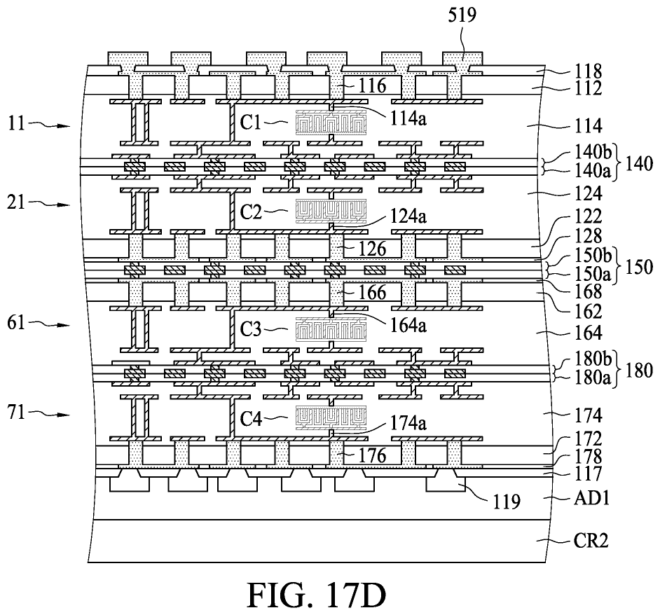

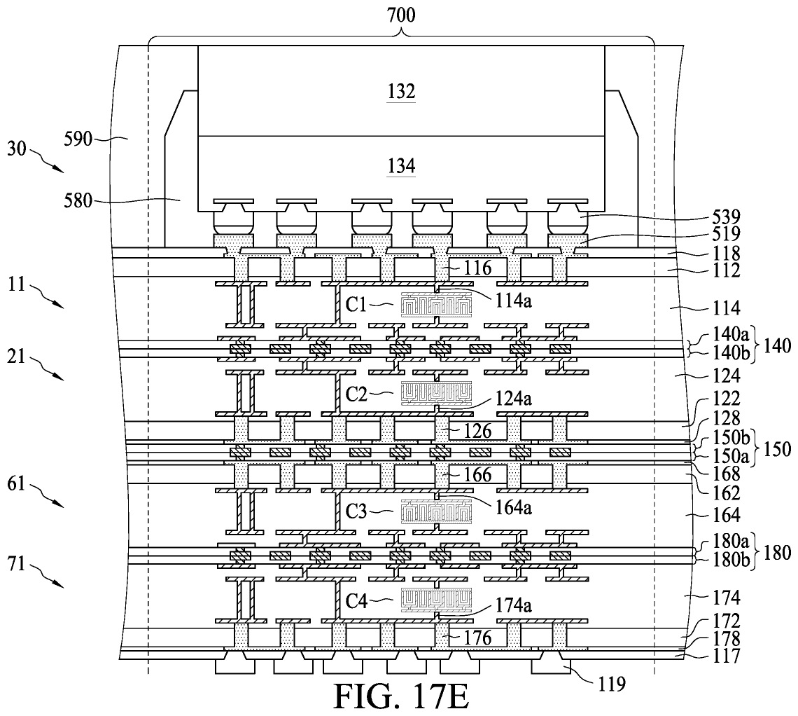

In some embodiments, the semiconductor structure 700 can also be manufactured by the method M1 by repeating some of the steps. FIGS. 17A to 17E show cross-sectional view of one or more stages of the method M1 for manufacturing the semiconductor structure 700 according to one embodiment of the present disclosure.

As shown in FIG. 17A, steps S110 to S130 can be performed so that the wafer 11 and the wafer 21 can be bonded. In some embodiments, the processes shown in FIGS. 7A to 7D can be adopted to form the structure shown in FIG. 17A.

Steps S110 to S120 can be repeated again for receiving the wafer 61 and the wafer 71. The step S130 can also be repeated for bonding the wafer 61 and the wafer 71. After the wafer 61 and the wafer 71 are bonded, the sub-bonding layer 150a can be formed on the wafer 21, and the sub-bonding layer 150b can be formed on the wafer 61. Afterwards, the wafer 61 can be further bonded to the wafer 21 with the bonding layer 150 formed by bonding the sub-bonding layers 150a and 150b. As a result, the four wafers 11, 21, 61, and 71 can be stacked as shown in FIG. 17B.

After the four wafers 11, 21, 61, and 71 are stacked, the semiconductive layer 172 can be ground so as to expose the via 176, and the RDL 178 can be formed on the semiconductive layer 172 and the via 176. The passivation layer 117 can be formed on the RDL 178 with openings for receiving the conductive bumps 119 later as shown in FIG. 17B.

After the conductive bumps 119 is formed on the passivation layer 117 and coupled to the RDL 178, the adhesive layer AD1 can be applied to the wafer 71 so as to protect the conductive bumps 119 and adhere a carrier CR2 to the wafer stacking structure as shown in FIG. 17C. In such case, the carrier CR2 is able to provide the supporting strength for the following processes, including grinding the semiconductive layer 112 to expose the via 116 therein, forming the RDL 118 on the semiconductive layer 112 and the via 116, and forming the bump pads 519 on the RDL 118 as shown in FIG. 17D.

In steps S140 and S150, a plurality of power management dies 130 can be received, and the plurality of conductive bumps 539 can be formed on the dielectric 134 of the power management dies 130. In such case, the power management dies 130 can be bonded over the wafer 11 by bonding the conductive bumps 539 to the bump pads 519 on the wafer 11 as shown in FIG. 17E. Furthermore, in some embodiments, after the power management dies 130 are bonded to the wafer 11, the underfill 580 can be applied to protect the connection between the conductive bumps 539 to the bump pads 519, and a molding process can be performed to mold the power management dies 130 on the wafer 11 with the molding layer 590. Finally, the carrier CR2 can be removed, and a sawing process can be performed to singulate the semiconductor structure 700 from the CoW structure.

Since the semiconductor structures 100, 200, 300, 400, 500, 600, and 700 allow the power management die to be coupled to the capacitors in the capacitor dies through interconnects extending along the stacking direction, the routing distances between the power management die and the capacitors can be shortened, therefore, the signal integrity as well as the power integrity can be improved. Furthermore, since the stacking structure of the capacitor dies allows to integrate more capacitance within a small area, the power efficiency of the power management die can also be improved.

In some embodiments, the semiconductor structures 100, 200, 300, 400, 500, 600, and 700 can be used to provide voltages for a system on chip (SoC). For example, each of the power management dies 130 in the semiconductor structures 100, 200, 300, 400, 500, 600, and 700 may include fully integrated voltage regulators (FIVRs) for the SoC. In some embodiments, the semiconductor structure 100, 200, 300, 400, 500, 600, or 700 be disposed in the same package with the SoC.

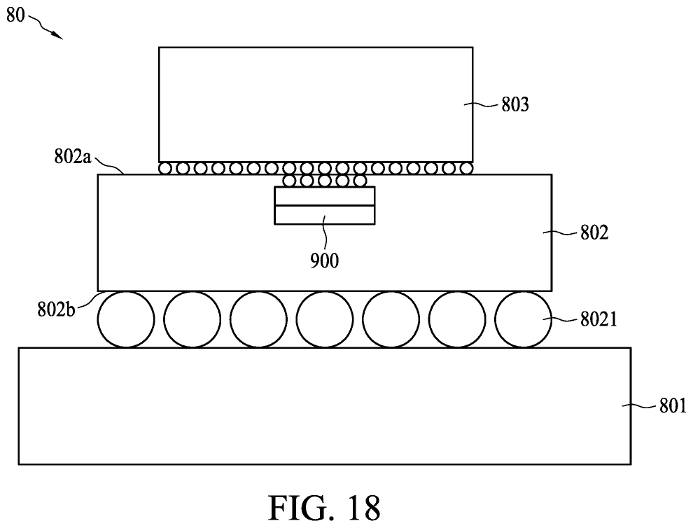

FIG. 18 shows a semiconductor device 80 according to one embodiment of the present disclosure. The semiconductor device 80 includes a printed circuit board (PCB) 801, a substrate 802, an SoC 803, and a semiconductor structure 900. In some embodiments, the semiconductor structure 900 can be any of the semiconductor structure 100, 200, 300, 400, 500, 600, and 700 or the like. In some embodiments, the substrate 802 can be a package substrate, and the SoC 803 can be disposed on a first surface 802a of the substrate 802. In addition, the semiconductor structure 900 is embedded in the substrate 802 with a plurality of conductive bumps 919 exposed from the first surface 802a of the substrate 802 and coupled to the SoC 803. That is, the semiconductor structure 900 is embedded in the substrate 802, and can be packaged in the same package as the SoC 803 on the substrate 802. In some embodiments, the substrate 802 further include a plurality of solder balls 8021 disposed on a second surface 802b so that the substrate 802 can be soldered to the PCB 801.

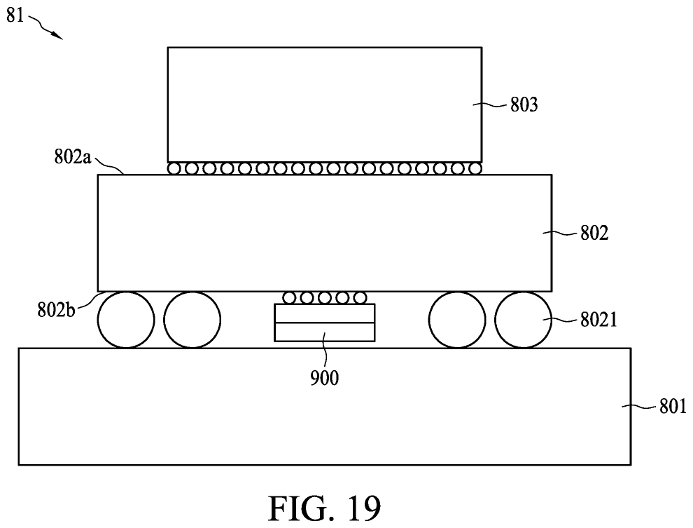

FIG. 19 shows a semiconductor device 81 according to one embodiment of the present disclosure. The semiconductor device 81 is similar to the semiconductor device 80. However, the differences between the semiconductor device 80 and the semiconductor device 81 is in that the semiconductor structure 900 is disposed on the second surface 802b of the substrate 802 in the semiconductor device 81. That is, the semiconductor structure 900 is disposed on a landside of the substrate 802 in the semiconductor device 81.

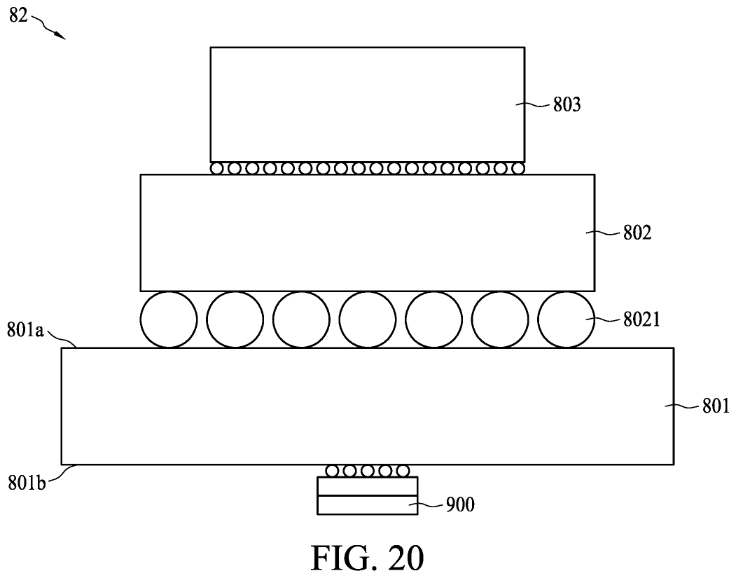

FIG. 20 shows a semiconductor device 82 according to one embodiment of the present disclosure. The semiconductor device 82 is similar to the semiconductor device 81. However, the semiconductor device 82 is different from the semiconductor device 80 in that while the substrate 802 is disposed on a first surface 801a of the PCB 801, the semiconductor structure 900 is disposed on a second surface 801b of the PCB 801 in the semiconductor device 82. That is, the semiconductor structure 900 is disposed on a landside of the PCB 801 in the semiconductor device 82.

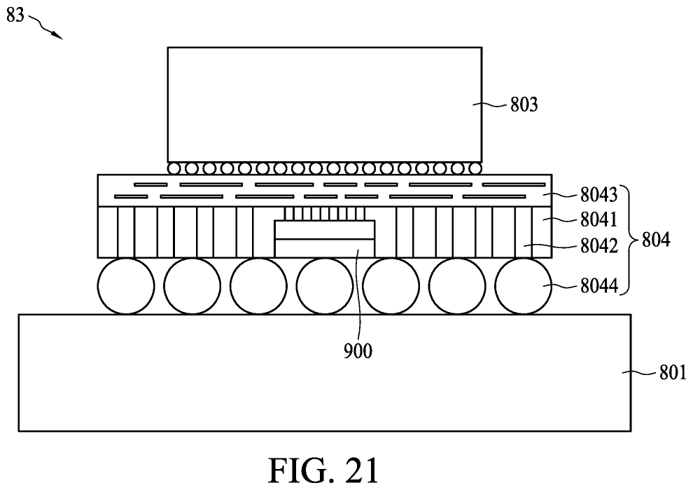

FIG. 21 shows a semiconductor device 83 according to one embodiment of the present disclosure. The semiconductor device 83 is similar to the semiconductor device 80. However, in the semiconductor device 83 a fan-out frame 804 including a copper pillars 8042, a molding 8041, a RDL 8043 and solder balls 8044 is disposed on the PCB 801. Also, the semiconductor structure 900 is embedded in the molding 8041 and is coupled to the SoC 803 through some of the copper pillars 8042 and the RDL 8043.

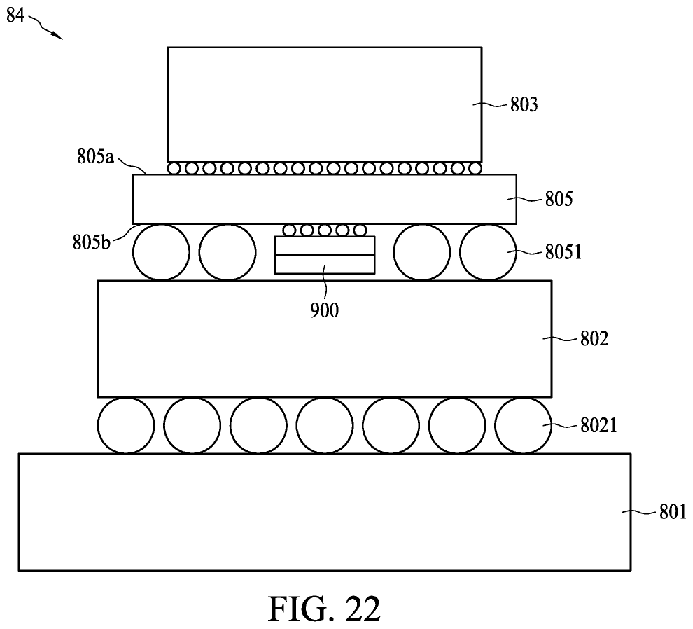

FIG. 22 shows a semiconductor device 84 according to one embodiment of the present disclosure. The semiconductor device 84 is similar to the semiconductor device 81. However, the semiconductor device 84 is different from the semiconductor device 81 in that the semiconductor device 84 further includes an interposer 805 disposed on the substrate 802, and the SoC 803 is disposed on a first surface 805a of the interposer 805. In addition, the interposer 805 includes a plurality of solder balls 8051 on a second surface 805b for soldering to the substrate 802. In such case, the semiconductor structure 900 can also be disposed on the second surface 805b of the interposer 805. That is, the semiconductor structure 900 is disposed on a landside of the interposer 805 in the semiconductor device 84. In some embodiments, the semiconductor devices 80, 81, 82, 83, and 84 can also be seen as semiconductor structures that includes the semiconductor structure 900.

In summary, the semiconductor devices and the method for manufacturing semiconductor devices provided by the embodiments of the present disclosure allow the power management die to be coupled to the capacitors in the capacitor dies through interconnects extending along the stacking direction, so the routing distances between the power management die and the capacitors can be shortened. As a result, the signal integrity as well as the power integrity can be improved. Furthermore, since the stacking structure of the capacitor dies allows to integrate more capacitance within a small area, the power efficiency of the power management die can also be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor structure comprising:
a first chip having a first 3-dimensional (3D) capacitor structure therein;
a second chip having a second 3D capacitor structure therein;
a first bonding layer bonding the first chip with the second chip; and
a power management die bonded with the second chip,
wherein the power management die is electrically connected to the first 3D capacitor structure and the second 3D capacitor structure through interconnects extending along a thickness of the semiconductor structure and across the first bonding layer.

2. The semiconductor structure of claim 1, wherein the power management die is bonded with the second chip by a second bonding layer, and from a top view, edges of the power management die are aligned with edges of the first chip and edges of the second chip.

3. The semiconductor structure of claim 1, wherein the first chip comprises a first dielectric, a first semiconductive layer over the first dielectric, a first via extending through the first semiconductive layer, a first RDL over the first semiconductive layer and the first via, and the first 3D capacitor structure is within the first dielectric.

4. The semiconductor structure of claim 3, wherein the first dielectric of the first chip is in proximity to a second dielectric of the second chip, the first semiconductive layer of the first chip is in proximity to the second dielectric of the second chip, or the first semiconductive layer of the first chip is in proximity to a second semiconductive layer of the second chip; and
wherein the first bonding layer is in contact with the first RDL or in contact with the first dielectric.

5. The semiconductor structure of claim 1, wherein the power management die is bonded with the second chip by a plurality of first conductive bumps, and the semiconductor structure further comprising:
an underfill disposed over the second chip and surrounding the plurality of first conductive bumps; and
a molding layer disposed on the second chip and surrounding the power management die, the underfill, and the plurality of first conductive bumps.

6. The semiconductor structure of claim 1, wherein the first chip has a first surface and a second surface opposite to the first surface, the first chip further comprises a plurality of second conductive bumps on the first surface of the first chip, and the second surface of the first chip contacts the first bonding layer.

7. The semiconductor structure of claim 1, wherein a capacitance density of the first chip and a capacitance density of the second chip are respectively greater than 1 μF/mm².

8. The semiconductor structure of claim 1, wherein the first 3D capacitor structure comprises:
a top metal plate;
a bottom metal plate over the top metal plate; and
a plurality of 3D capacitor unit cells formed between the top metal plate and the bottom metal plate.

9. The semiconductor structure of claim 8, wherein each of the 3D capacitor unit cells comprises:
a first conductor film, comprising:
a first portion connected to the bottom metal plate; and
a second portion connected to the first portion and extending toward the top metal plate from the bottom metal plate; and
a second conductor film adjacent to the first conductor film and connected to the top metal plate and extending toward the bottom metal plate from the top metal plate,
wherein the second conductor film is vertically interleaving with the second portion of the first conductor film.

10. The semiconductor structure of claim 1, wherein the first 3D capacitor structure is a cylindrical-type capacitor.

11. The semiconductor structure of claim 1, further comprising:
a printed circuit board (PCB);
a substrate disposed on the PCB; and
a system on chip (SoC) disposed on a first surface of the substrate and coupled to the first chip, the second chip, and the power management die.

12. The semiconductor structure of claim 11, wherein:
the first chip, the second chip, and the power management die are embedded in the substrate with a plurality of conductive bumps exposed from the first surface of the substrate; or
the first chip, the second chip, and the power management die are disposed on a second surface of the substrate.

13. A method for manufacturing a semiconductor structure, comprising:
forming a bonding between a first wafer having a plurality of first 3-dimensional (3D) capacitor structures therein and a second wafer having a plurality of second 3D capacitor structures therein to bond the first wafer with the second wafer;
bonding a plurality of power management dies over the second wafer; and
performing a sawing process to form the semiconductor structure including a first chip, a second chip, a first bonding layer, one of the plurality of power management dies, one of the plurality of first 3D capacitor structures in the first chip and one of the plurality of second 3D capacitor structures in the second chip,
wherein the one of the plurality of power management dies is electrically connected to the one of the plurality of first 3D capacitor structures and the one of the plurality of second 3D capacitor structures through interconnects extending along a thickness of the semiconductor structure and across the first bonding layer.

14. The method of claim 13, wherein the step of forming the bonding between the first wafer and the second wafer comprises forming a first sub-bonding layer over the first wafer, forming a second sub-bonding layer over the second wafer, and bonding the first sub-bonding layer with the second sub-bonding layer.

15. The method of claim 14, further comprising:
receiving the first wafer comprising a first dielectric, a first semiconductive layer over the first dielectric, a first via extending through the first semiconductive layer, and the plurality of first 3D capacitor structures are within the first dielectric;
attaching a carrier on the first dielectric of the first wafer;
grinding the first semiconductive layer of the first wafer to expose the first via; and
forming a first RDL on the first semiconductive layer and the first via of the first wafer;
wherein the first sub-bonding layer is formed on the first RDL.

16. The method of claim 14, further comprising:
receiving the first wafer comprising a first dielectric, a first semiconductive layer over the first dielectric, and the plurality of first 3D capacitor structures are within the first dielectric;
attaching a carrier on the first dielectric of the first wafer;
forming a first via in the first semiconductive layer; and
forming a first RDL on the first semiconductive layer and the first via of the first wafer;
wherein the first sub-bonding layer is formed on the first RDL.

17. The method of claim 14, further comprising:
receiving the first wafer comprising a first dielectric, a first semiconductive layer over the first dielectric, and the plurality of first 3D capacitor structures are within the first dielectric,
wherein the first sub-bonding layer is formed on the first dielectric.

18. The method of claim 13, further comprising:
receiving a power management wafer comprising the plurality of power management dies;
wherein the step of bonding the plurality of power management dies over the second wafer comprises:
forming a third sub-bonding layer over the second wafer;
forming a fourth sub-bonding layer over the power management wafer; and
bonding the third sub-bonding layer with the fourth sub-bonding layer.

19. The method of claim 13, wherein the each of the plurality of first 3D capacitor structures comprises a top metal plate, a bottom metal plate, and a plurality of 3D capacitor unit cells formed between the top metal plate and the bottom metal plate.

20. The method of claim 19, further comprising arranging the plurality of 3D capacitor unit cells as a rectangular array or a hexagonal array.
